(19) United States
(12) Patent Application Publication
(10) Pub. No.: US 2009/0056811 A1
(43) Pub. Date: Mar. 5, 2009

(54) POLYMER COMPOUND AND POLYMER LIGHT EMITTING DEVICE USING THE SAME

(75) Inventors: Takanobu Noguchi, Ibaraki (JP); Tomoyuki Suzuki, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Sumitomo Chemical Company, Limited, Chuo-ku, Tokyo (JP)

(21) Appl. No.: 12/159,883

(22) PCT Filed: Jan. 12, 2007
(86) PCT No.: PCT/JP07/50746

§ 371 Date: Jul. 2, 2008

(30) Foreign Application Priority Data
Jan. 16, 2006 (JP) 2006-007046

(51) Int. Cl. H01L 31/042; C08G 79/02; H01L 51/05; H01J 1/63

(52) U.S. Cl. 136/263; 528/392; 528/168; 313/504; 257/40; 257/E51.005; 257/E51.012

(57) ABSTRACT

A polymer compound comprising a repeating unit of the formula (1):

—[Ar₁—(X₁)ₙ]— (1)

(wherein, Ar₁ represents an arylene group having a group of the following formula (2), X₁ represents —CR¹═CR²— (R¹ and R² represent a hydrogen atom or substituent) or —C≡C—, and n represents 0 or 1.)

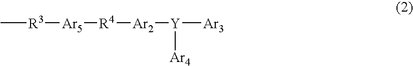

(wherein, Ar₂ represents an arylene group, Ar₅ represents a direct bond, arylene group or the like, R³ and R⁴ represent a direct bond, substituent or the like, Ar₃ and Ar₄ represent an aryl group or the like, and Y represents the following formula:

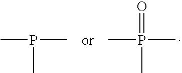

Here, when Ar₅ is a direct bond, R³ is a direct bond.).

### TECHNICAL FIELD

The present invention relates to a polymer compound and a polymer light emitting device using the polymer compound.

### BACKGROUND ART

Light emitting materials of high molecular weight soluble in a solvent are variously investigated since they can form a layer in a light emitting device by an application method. As examples of the light emitting materials, a polyarylenevinylene having a triarylamine group on the side chain (U.S. Pat. No. 6,414,104), a polyarylene having an aromatic heterocyclic group on the side chain (JP-A No. 2004-277568), a polyfluorene having a quinoline group on the side chain (J. of Polymer Science, Part A, Polymer Chemistry, Vol. 43, 859-869 (2005)), a polyfluorene having a triarylamine group on the side chain (Advanced Materials, 14, No. 11, 809-811 (2002)) and the like are suggested

### DISCLOSURE OF THE INVENTION

An object of the present invention is to provide a novel polymer compound which is useful particularly as a light emitting material and having heat resistance and fluorescence intensity of practical level, and a polymer light emitting device using this polymer compound.

The present inventors have intensively studied, resultantly leading to completion of the invention. That is, the present invention provides a polymer compound comprising a repeating unit of the following formula (1):

—[Ar₁—(X₁)ₙ]— (1)

(wherein, Ar₁ represents an arylene group having a group of the following formula (2), a divalent heterocyclic group having a group of the following formula (2) or a divalent aromatic amine group having a group of the following formula (2), X₁ represents —CR¹═CR²— (wherein, R¹ and R² represent each independently a hydrogen atom, alkyl group, aryl group, monovalent heterocyclic group or cyano group) or —C≡C—, and n represents 0 or 1.)

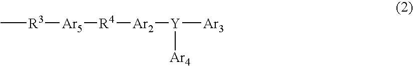

(wherein, Ar₂ represents an arylene group, divalent heterocyclic group or divalent aromatic amine group, Ar₅ represents a direct bond, arylene group, divalent heterocyclic group or divalent aromatic amine group, R³ and R⁴ represent each independently a direct bond, —R⁵—, —O—R⁵—, —R⁵—O—, —R⁵—C(O)O—, —R⁵—OC(O)—, —R⁵—N(R⁶)—, —O—, —S—, —C(O)O—, —C(O)—, —CR⁷═CR⁸— or —C≡C— (wherein, R⁵ represents an alkylene group or alkenylene group, R⁶, R⁷ and R⁸ represent each independently a hydrogen atom, alkyl group, aryl group, monovalent heterocyclic group or cyano group.), Ar₃ and Ar₄ represent each independently an aryl group, monovalent heterocyclic group or monovalent aromatic amine group, and Y represents the following formula:

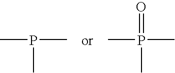

Here, when Ar₅ is a direct bond, R³ is a direct bond.).

### MODE FOR CARRYING OUT THE INVENTION

The polymer compound of the present invention is a polymer compound containing a repeating unit of the above-described formula (1). The polymer compound of the present invention may contain only one kind of or two or more kinds of repeating units of the above-described formula (1).

In the above-described formula (1), Ar₁ represents an arylene group having a group of the above-described formula (2), a divalent heterocyclic group having a group of the above-described formula (2) or a divalent aromatic amine group having a group of the above-described formula (2), and from the standpoint of fluorescence intensity, represents preferably an arylene group having a group of the above-described formula (2) or a divalent heterocyclic group having a group of the above-described formula (2).

Further, Ar₁ may contain a substituent such as an alkyl group, alkoxy group, alkylthio group, alkylsilyl group, alkylamino group, aryl group, aryloxy group, arylalkyl group, arylalkoxy group, arylalkenyl group, arylalkynyl group, arylamino group, monovalent heterocyclic group, cyano group and the like, in addition to groups of the above-described formula (2). When Ar₁ has two or more of substituents, they may be the same or mutually different. Details of these substituents are the same as those specifically explained and illustrated as R in the following illustrated arylene groups (the following formulae 1 to 38, A to I, K).

In the above-described formula (1), the arylene group means an atomic group remaining after removal of two hydrogen atoms from an aromatic hydrocarbon. The carbon number of the arylene group is usually about from 6 to 60. This carbon number does not include the carbon number of a substituent. Here, the aromatic hydrocarbon includes also those having a condensed ring and those formed by connecting two or more independent benzene rings or condensed rings directly or via a group such as a vinylene group and the like.

Examples of the arylene group include phenylene groups (for example, the following formulae 1 to 3), naphthalenediyl groups (the following formulae 4 to 13), anthracenylene groups (the following formulae 14 to 19), biphenylene groups (the following formulae 20 to 25), triphenylene groups (the following formulae 26 to 28), condensed ring compound groups (the following formulae 29 to 38), stilbene-diyl groups (the following formulae A to D), distilbene-diyl groups (the following formulae E, F), benzofluorene-diyl groups (the following formulae G, H, I, K) and the like. Of them, preferable are phenylene groups, naphthalenediyl groups, biphenylene groups, fluorine-diyl groups (the following formulae 36 to 38), stilbene-diyl groups (the following formulae A to D), distilbene-diyl groups (the following formulae E,F) and benzofluorene-diyl groups (the following formulae G, H, I, K).

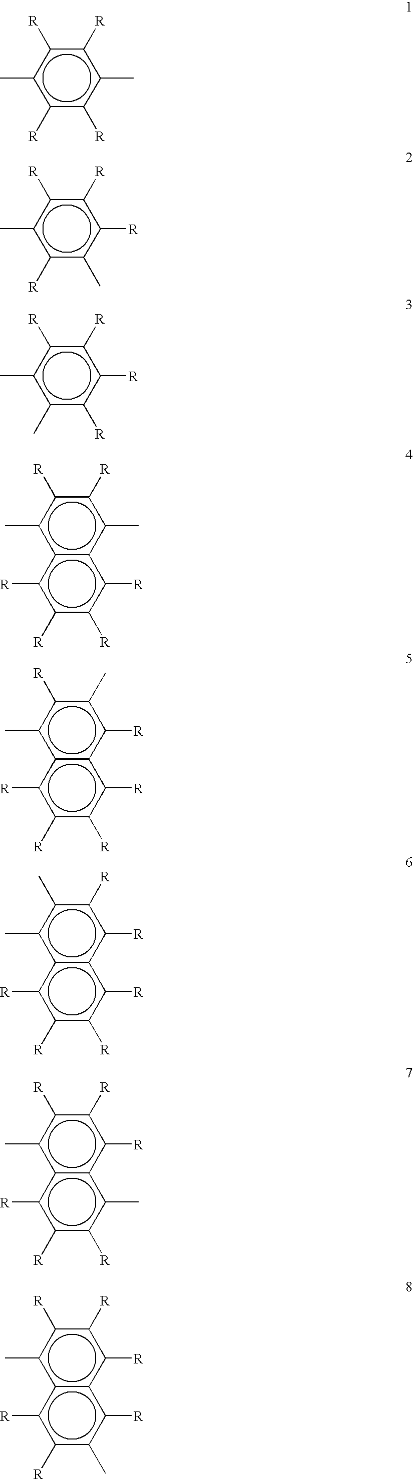

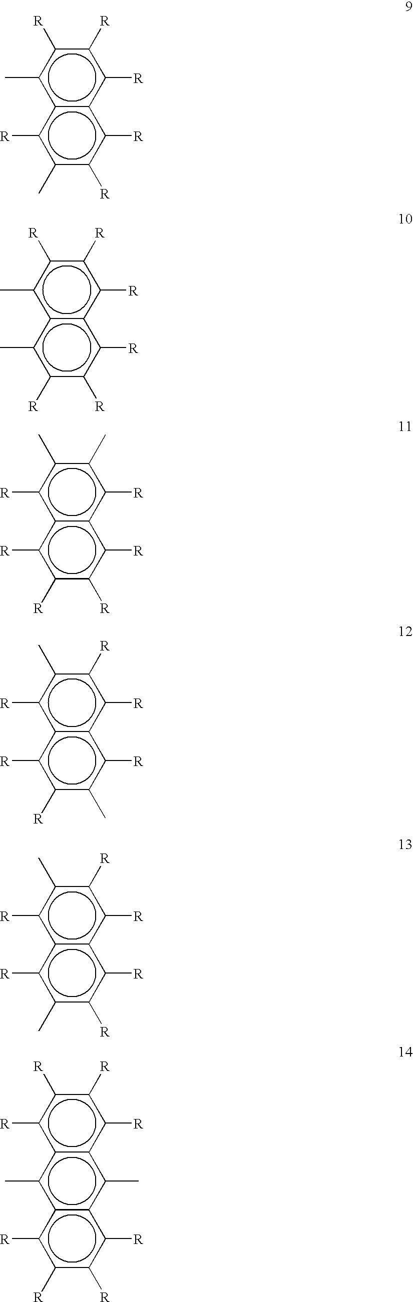

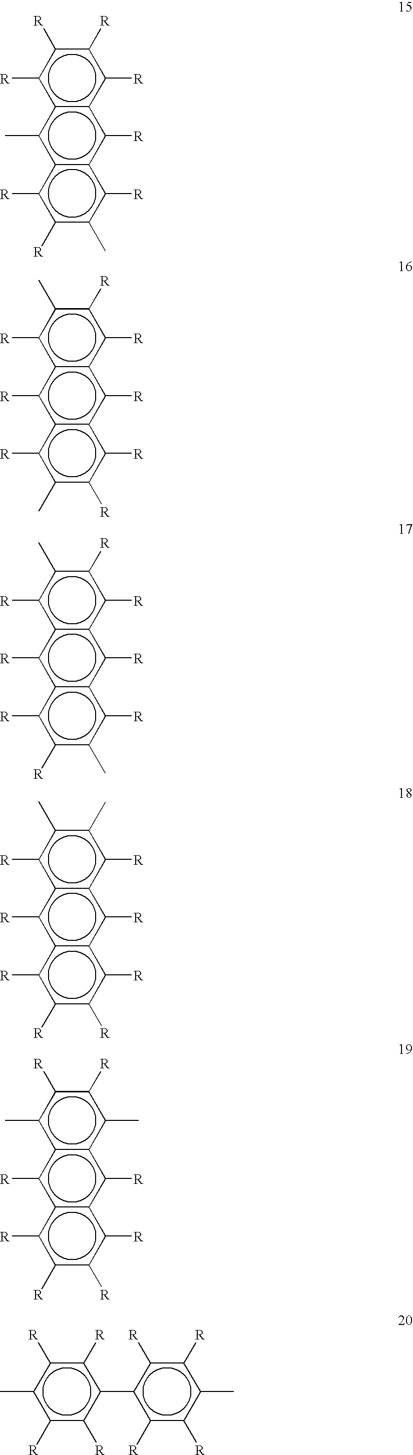

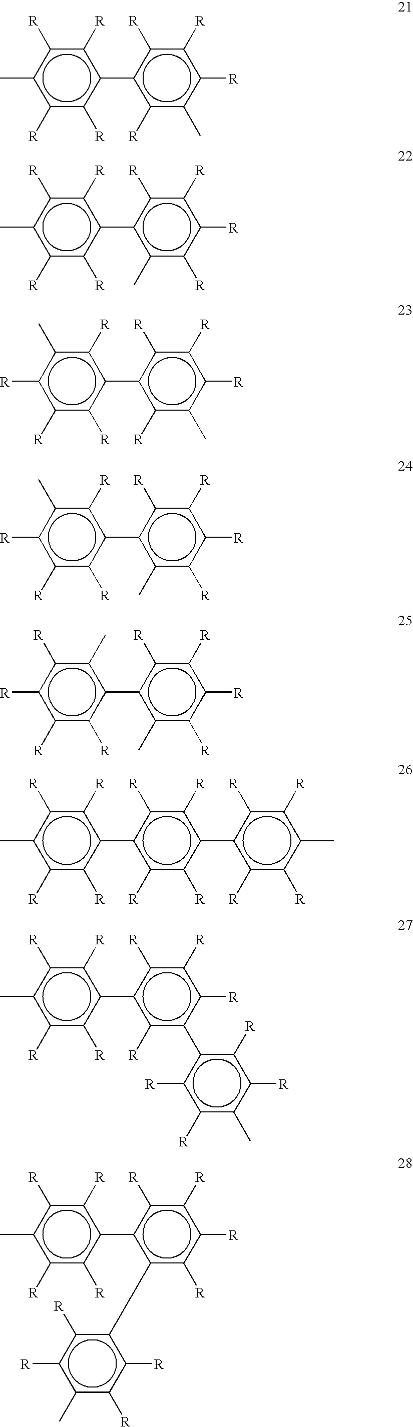

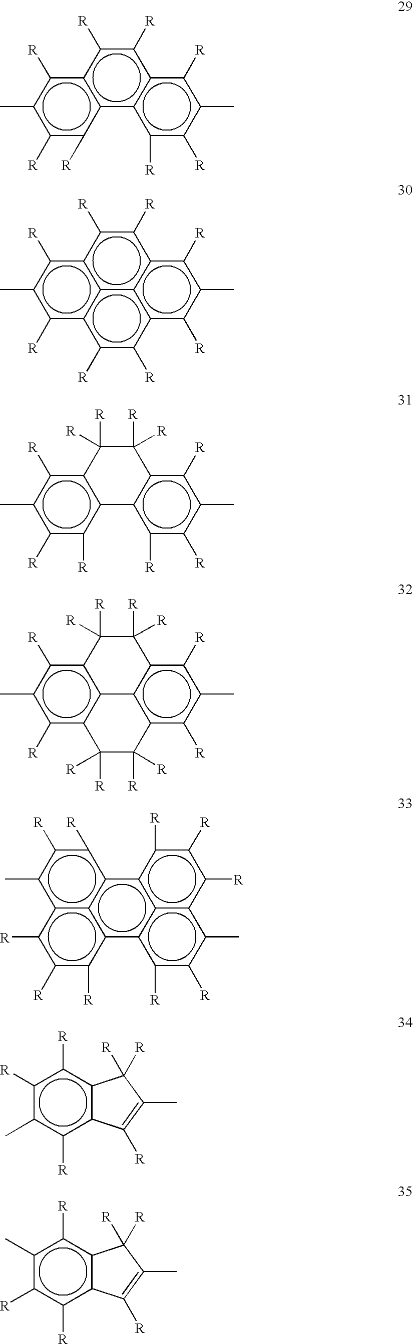

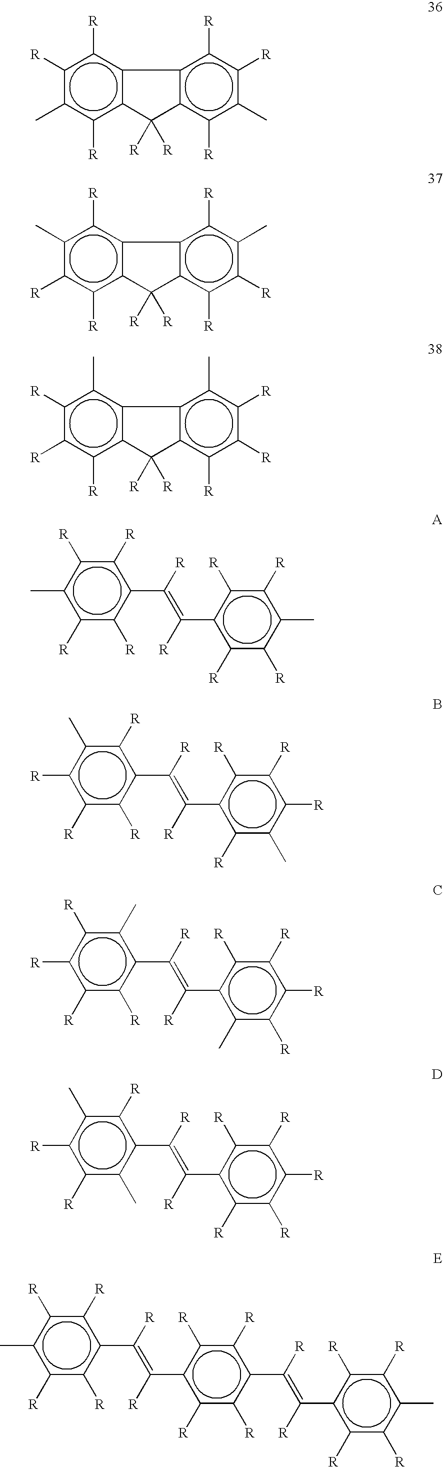

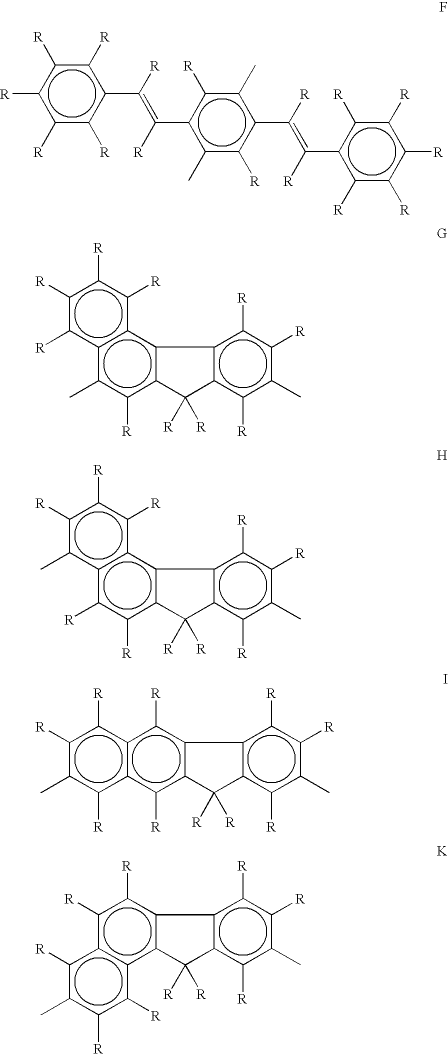

In these illustrated arylene groups (the above-described formulae 1 to 38, A to I, K), Rs represent each independently a group of the above-described formula (2), hydrogen atom, alkyl group, alkoxy group, alkylthio group, alkylsilyl group, alkylamino group, aryl group, aryloxy group, arylalkyl group, arylalkoxy group, arylalkenyl group, arylalkynyl group, arylamino group, monovalent heterocyclic group or cyano group. In these illustrated arylene groups, two or more of Rs are present in one structural formula, and these may be the same as or different from each other. Here, at least one of Rs is a group of the above-described formula (2).

The alkyl group may be linear, branched or cyclic, and the carbon number thereof is usually about from 1 to 20. Examples of the alkyl group include a methyl group, ethyl group, propyl group, i-propyl group, butyl group, i-butyl group, t-butyl group, pentyl group, hexyl group, cyclohexyl group, heptyl group, octyl group, 2-ethylhexyl group, nonyl group, decyl group, 3,7-dimethyloctyl group, lauryl group and the like, and preferable are a pentyl group, hexyl group, octyl group, 2-ethylhexyl group, decyl group and 3,7-dimethyloctyl group.

The alkoxy group may be linear, branched or cyclic, and the carbon number thereof is usually about from 1 to 20. Examples of the alkoxy group include a methoxy group, ethoxy group, propyloxy group, i-propyloxy group, butoxy group, i-butoxy group, t-butoxy group, pentyloxy group, hexyloxy group, cyclohexyloxy group, heptyloxy group, octyloxy group, 2-ethylhexyloxy group, nonyloxy group, decyloxy group, 3,7-dimethyloctyloxy group, lauryloxy group and the like, and preferable are a pentyloxy group, hexyloxy group, octyloxy group, 2-ethylhexyloxy group, decyloxy group and 3,7-dimethyloctyloxy group.

The alkylthio group may be linear, branched or cyclic, and the carbon number thereof is usually about from 1 to 20. Examples of the alkylthio group include a methylthio group, ethylthio group, propylthio group, i-propylthio group, butylthio group, i-butylthio group, t-butylthio group, pentylthio group, hexylthio group, cyclohexylthio group, heptylthio group, octylthio group, 2-ethylhexylthio group, nonylthio group, decylthio group, 3,7-dimethyloctylthio group, laurylthio group and the like, and preferable are a pentylthio group, hexylthio group, octylthio group, 2-ethylhexylthio group, decylthio group and 3,7-dimethyloctylthio group.

The alkylsilyl group may be linear, branched or cyclic, and the carbon number thereof is usually about from 1 to 60. Examples of the alkylsilyl group include a methylsilyl group, ethylsilyl group, propylsilyl group, i-propylsilyl group, butylsilyl group, i-butylsilyl group, t-butylsilyl group, pentylsilyl group, hexylsilyl group, cyclohexylsilyl group, heptylsilyl group, octylsilyl group, 2-ethylhexylsilyl group, nonylsilyl group, decylsilyl group, 3,7-dimethyloctylsilyl group, laurylsilyl group, trimethylsilyl group, ethyldimethylsilyl group, propyldimethylsilyl group, i-propyldimethylsilyl group, butyldimethylsilyl group, t-butyldimethylsilyl group, pentyldimethylsilyl group, hexyldimethylsilyl group, heptyldimethylsilyl group, octyldimethylsilyl group, 2-ethylhexyl-dimethylsilyl group, nonyldimethylsilyl group, decyldimethylsilyl group, 3,7-dimethyloctyl-dimethylsilyl group, lauryldimethylsilyl group and the like, and preferable are a pentylsilyl group, hexylsilyl group, octylsilyl group, 2-ethylhexylsilyl group, decylsilyl group, 3,7-dimethyloctylsilyl group, pentyldimethylsilyl group, hexyldimethylsilyl group, octyldimethylsilyl group, 2-ethylhexyldimethylsilyl group, decyldimethylsilyl group and 3,7-dimethyloctyldimethylsilyl group.

The alkylamino group may be linear, branched or cyclic, and may be a monoalkylamino group or dialkylamino group, and the carbon number thereof is usually about from 1 to 40. Examples of the alkylamino group include a methylamino group, dimethylamino group, ethylamino group, diethylamino group, propylamino group, i-propylamino group, butylamino group, i-butylamino group, t-butylamino group, pentylamino group, hexylamino group, cyclohexylamino group, heptylamino group, octylamino group, 2-ethylhexylamino group, nonylamino group, decylamino group, 3,7-dimethyloctylamino group, laurylamino group and the like, and preferable are a pentylamino group, hexylamino group, octylamino group, 2-ethylhexylamino group, decylamino group and 3,7-dimethyloctylamino group.

The aryl group has a carbon number of usually about from 6 to 60. Examples of the aryl group include a phenyl group, C₁ to C₁₂ alkoxyphenyl groups (“C₁ to C₁₂ alkoxy” means that the alkoxy portion has a carbon number of 1 to 12, being applicable also in the following descriptions), C₁ to C₁₂ alkylphenyl groups (“C₁ to C₁₂ alkyl” means that the alkyl portion has a carbon number of 1 to 12, being applicable also in the following descriptions), 1-naphthyl group, 2-naphthyl group and the like, and preferable are C₁ to C₁₂ alkoxyphenyl groups and C₁ to C₁₂ alkylphenyl groups.

The aryloxy group has a carbon number of usually about from 6 to 60. Examples of the aryloxy group include a phenoxy group, C₁ to C₁₂ alkoxyphenoxy groups, C₁ to C₁₂ alkylphenoxy groups, 1-naphthyloxy group, 2-naphthyloxy group and the like, and preferable are C₁ to C₁₂ alkoxyphenoxy groups and C₁ to C₁₂ alkylphenoxy groups.

The arylalkyl group has a carbon number of usually about from 7 to 60. Examples of the arylalkyl group include phenyl-C₁ to C₁₂ alkyl groups, C₁ to C₁₂ alkoxyphenyl-C₁ to C₁₂ alkyl groups, C₁ to C₁₂ alkylphenyl-C₁ to C₁₂ alkyl groups, 1-naphthyl-C₁ to C₁₂ alkyl groups, 2-naphthyl-C₁ to C₁₂ alkyl groups and the like, and preferable are C₁ to C₁₂ alkoxyphenyl-C₁ to C₁₂ alkyl groups and C₁ to C₁₂ alkylphenyl-C₁ to C₁₂ alkyl groups.

The arylalkoxy group has a carbon number of usually about from 7 to 60. Examples of the arylalkoxy group include phenyl-C₁ to C₁₂ alkoxy groups, C₁ to C₁₂ alkoxyphenyl-C₁ to C₁₂ alkoxy groups, C₁ to C₁₂ alkylphenyl-C₁ to C₁₂ alkoxy groups, 1-naphthyl-C₁ to C₁₂ alkoxy groups, 2-naphthyl-C₁ to C₁₂ alkoxy groups and the like, and preferable are C₁ to C₁₂ alkoxyphenyl-C₁ to C₁₂ alkoxy group and C₁ to C₁₂ alkylphenyl-C₁ to C₁₂ alkoxy groups.

The arylalkenyl group has a carbon number of usually about from 8 to 60. Examples of the arylalkenyl group include phenyl-C₂ to C₁₂ alkenyl groups (“C₂ to C₁₂ alkenyl” means that the alkenyl portion has a carbon number of 2 to 12, being applicable also in the following descriptions), C₁ to C₁₂ alkoxyphenyl-C₂ to C₁₂ alkenyl groups, C₁ to C₁₂ alkylphenyl-C₂ to C₁₂ alkenyl groups, 1-naphthyl-C₂ to C₁₂ alkenyl groups, 2-naphthyl-C₂ to C₁₂ alkenyl groups and the like, and preferable are C₁ to C₁₂ alkoxyphenyl-C₂ to C₁₂ alkenyl groups and C₁ to C₁₂ alkylphenyl-C₂ to C₁₂ alkenyl groups.

The arylalkynyl group has a carbon number of usually about from 8 to 60. Examples of the arylalkynyl group include phenyl-C₂ to C₁₂ alkynyl groups (“C₂ to C₁₂ alkynyl” means that the alkynyl portion has a carbon number of 2 to 12, being applicable also in the following descriptions), C₁ to C₁₂ alkoxyphenyl-C₂ to C₁₂ alkynyl groups, C₁ to C_{12b}alkylphenyl-C₂ to C₁₂ alkynyl groups, 1-naphthyl-C₂ to C₁₂ alkynyl groups, 2-naphthyl-C₂ to C₁₂ alkynyl groups and the like, and preferable are C₁ to C₁₂ alkoxyphenyl-C₂ to C₁₂ alkynyl groups and C₁ to C₁₂ alkylphenyl-C₂ to C₁₂ alkynyl groups.

The arylamino group has a carbon number of usually about from 6 to 60. Examples of the arylamino group include a phenylamino group, diphenylamino group, C₁ to C₁₂ alkoxyphenylamino groups, di(C₁ to C₁₂ alkoxyphenyl)amino groups, di(C₁ to C₁₂ alkylphenyl)amino groups, 1-naphthylamino group, 2-naphthyl-amino group and the like, and preferable are C₁ to C₁₂ alkylphenylamino groups and di(C₁ to C₁₂ alkylphenyl)amino groups.

In the above-described R, the monovalent heterocyclic group means an atomic group remaining after removal of one hydrogen atom from a heterocyclic compound. The monovalent heterocyclic group has a carbon number of usually about from 4 to 60 (here, the carbon number thereof does not include the carbon number of a substituent.). The heterocyclic compound indicates organic compounds having a cyclic structure in which atoms constituting the ring include not only a carbon atom but also heteroatoms such as oxygen, sulfur, nitrogen, phosphorus, boron and the like contained in the ring. Examples of the monovalent heterocyclic group include a thienyl group, C₁ to C₁₂ alkylthienyl groups, pyrrolyl group, furyl group, pyridyl group, C₁ to C₁₂ alkylpyridyl groups and the like, and preferable are a thienyl group, C₁ to C₁₂ alkylthienyl groups, pyridyl group and C₁ to C₁₂ alkylpyridyl groups.

When the above-described substituent is a group containing an alkyl chain, the alkyl chain may be interrupted by a heteroatom or a group containing a heteroatom. Examples of this heteroatom include an oxygen atom, sulfur atom, nitrogen atom and the like. Examples of the heteroatom or the group containing a heteroatom include the following groups.

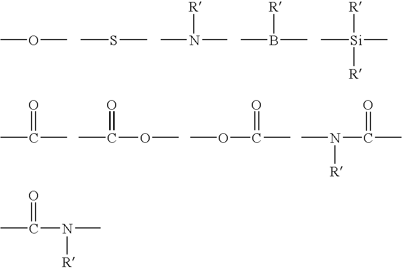

In the above-exemplified heteroatoms or groups containing a heteroatom, R's represent independently a hydrogen atom, alkyl group having a carbon number of 1 to 20, aryl group having a carbon number of 6 to 60 or a monovalent heterocyclic group having a carbon number of 4 to 60. The alkyl group, aryl group and monovalent heterocyclic group represented by R′ are the same as those explained and illustrated as the substituent represented by R in the above-illustrated arylene groups (the above-described formulae 1 to 38, A to I, K).

For enhancing the solubility of a polymer compound of the present invention in a solvent, it is preferable that the configuration of a repeating unit shows little symmetry and it is preferable that a cyclic or branched alkyl chain is contained in one or more of Rs. Two or more of Rs may be connected to form a ring. Of Rs, the substituent containing an alkyl group is linear, branched or cyclic, or a combination thereof. Examples of no-linear cases include an isoamyl group, 2-ethylhexyl group, 3,7-dimethyloctyl group, cyclohexyl group, 4-C₁ to C₁₂ alkylcyclohexyl groups and the like.

In the above-described formula (1), the divalent heterocyclic group means an atomic group remaining after removal of two hydrogen atoms from a heterocyclic compound. The divalent heterocyclic group has a carbon number of usually about from 4 to 60 (here, the carbon number thereof does not include the carbon number of a substituent.). The heterocyclic compound indicates organic compounds having a cyclic structure in which atoms constituting the ring include not only a carbon atom but also heteroatoms such as oxygen, sulfur, nitrogen, phosphorus, boron and the like contained in the ring. As the divalent heterocyclic group, divalent aromatic heterocyclic groups (namely, divalent heterocyclic groups having an aromatic property) are preferable. Examples of the divalent heterocyclic group include the following groups.

a) Groups containing nitrogen as a heteroatom

pyridine-diyl groups (the following formulae 39 to 44), diazaphenylene groups (the following formulae 45 to 48), quinolinediyl groups (the following formulae 49 to 63), quinoxalinediyl groups (the following formulae 64 to 68), acridinediyl groups (the following formulae 69 to 72), bipyridyldiyl groups (the following formulae 73 to 75), phenanthrolinediyl groups (the following formulae 76 to 78) and the like

b) Groups containing silicon, nitrogen, oxygen, sulfur, selenium and the like as a heteroatom and having a fluorene structure (meaning a structure in which one carbon atom constituting a 5-membered ring in the fluorene ring is substituted by an atom such as silicon, nitrogen, oxygen, sulfur, selenium and the like or a group containing these atoms) (the following formulae 79 to 93)

c) 5-membered ring heterocyclic groups containing silicon, nitrogen, oxygen, sulfur, selenium and the like as a heteroatom (the following formulae 94 to 98)

d) 5-membered ring condensed heterocyclic groups containing silicon, nitrogen, oxygen, sulfur, selenium and the like as a heteroatom (the following formulae 99 to 108)

e) 5-membered ring heterocyclic groups containing sulfur and the like as a heteroatom, connecting at an α-position of the heteroatom to form a dimer or oligomer (the following formulae 109 to 110)

f) 5-membered ring heterocyclic groups containing silicon, nitrogen, oxygen, sulfur, selenium and the like as a heteroatom, connecting at an α-position of the heteroatom to a phenyl group (the following formulae 111 to 117)

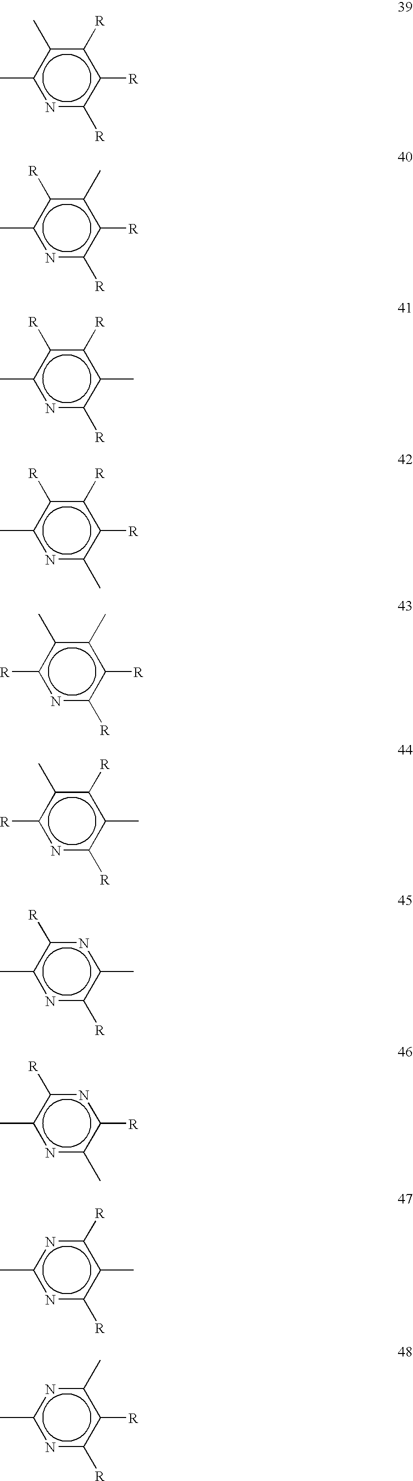

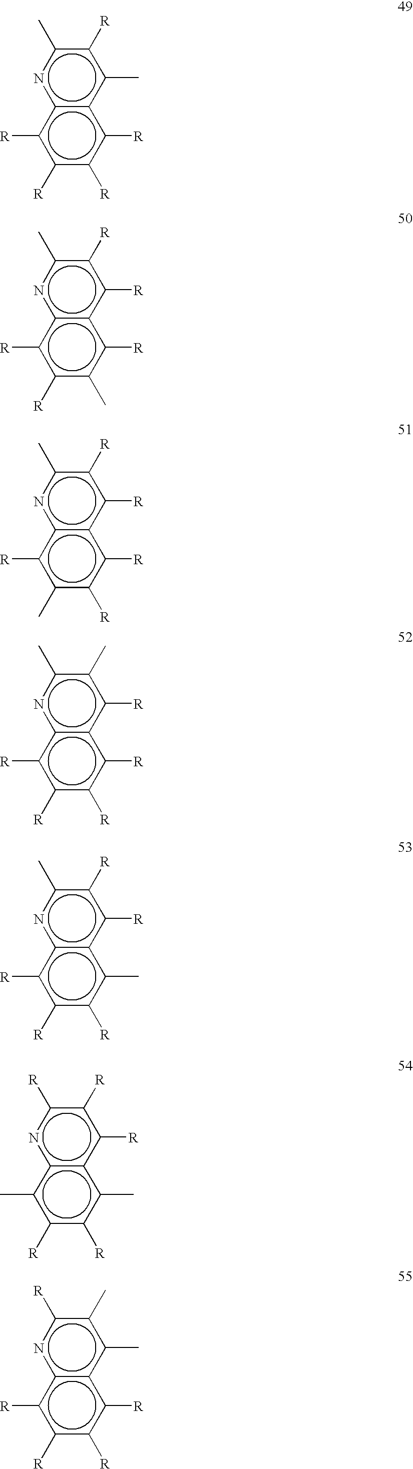

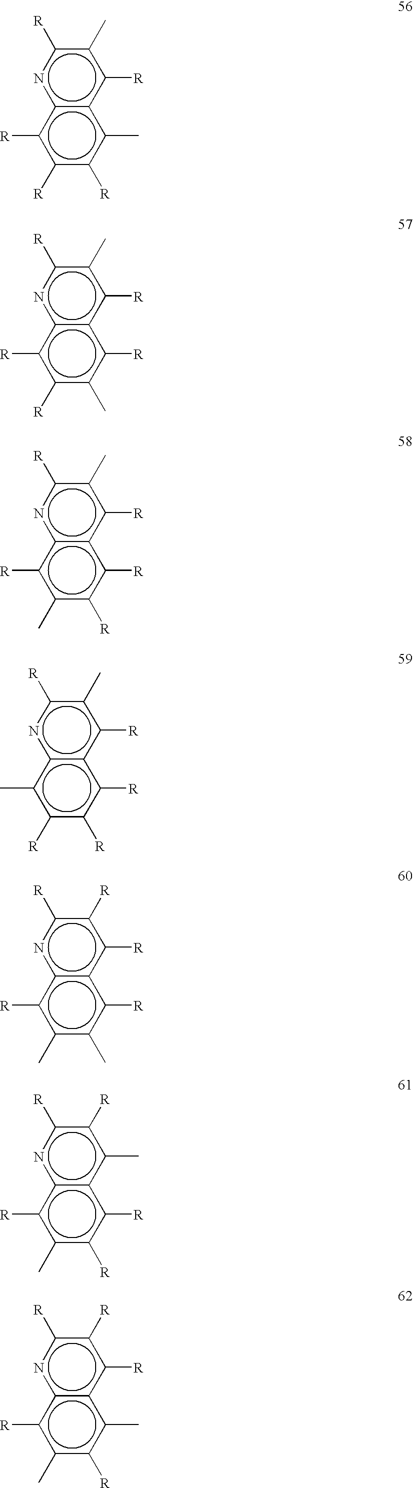

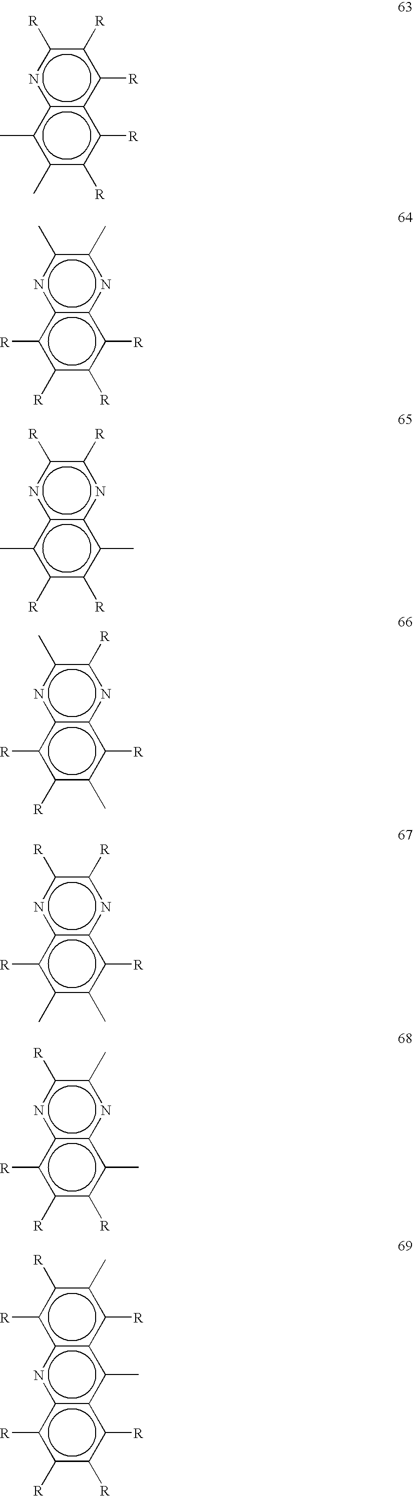

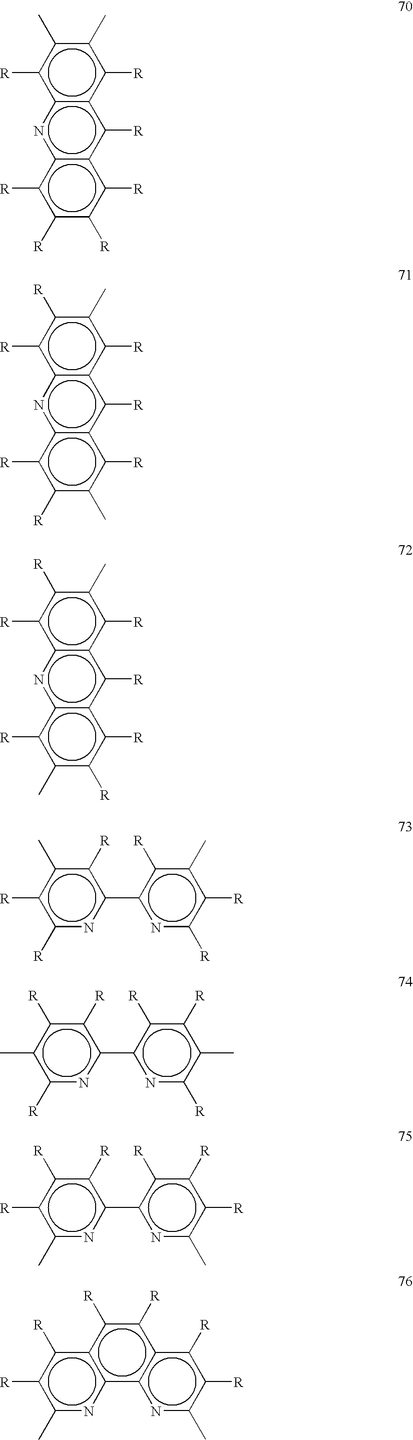

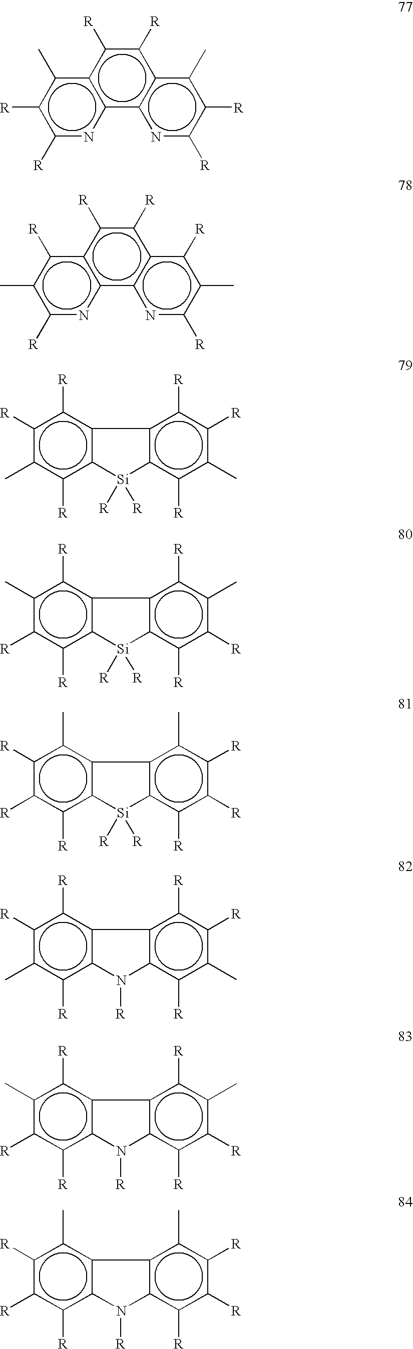

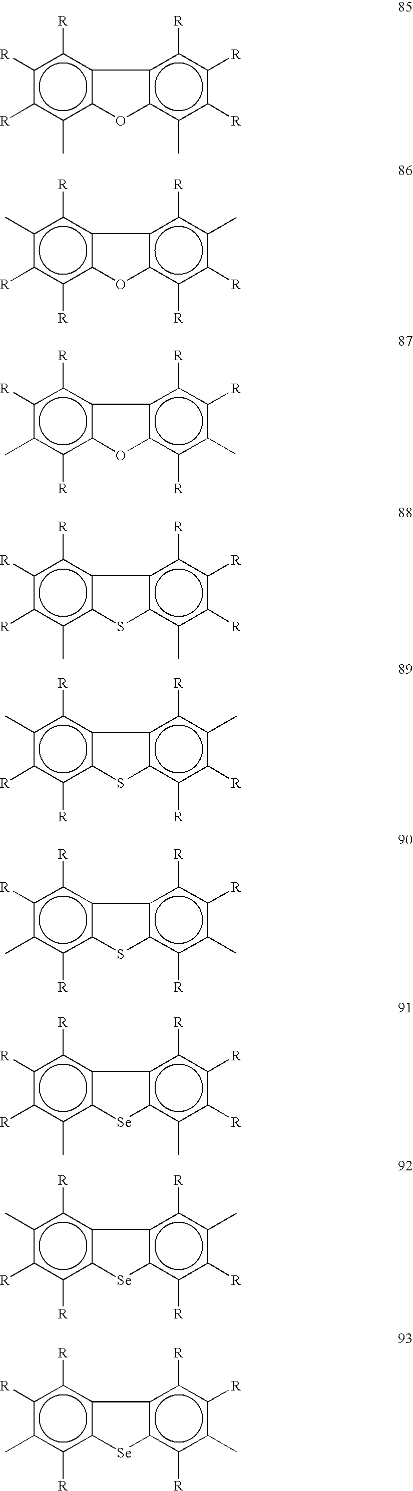

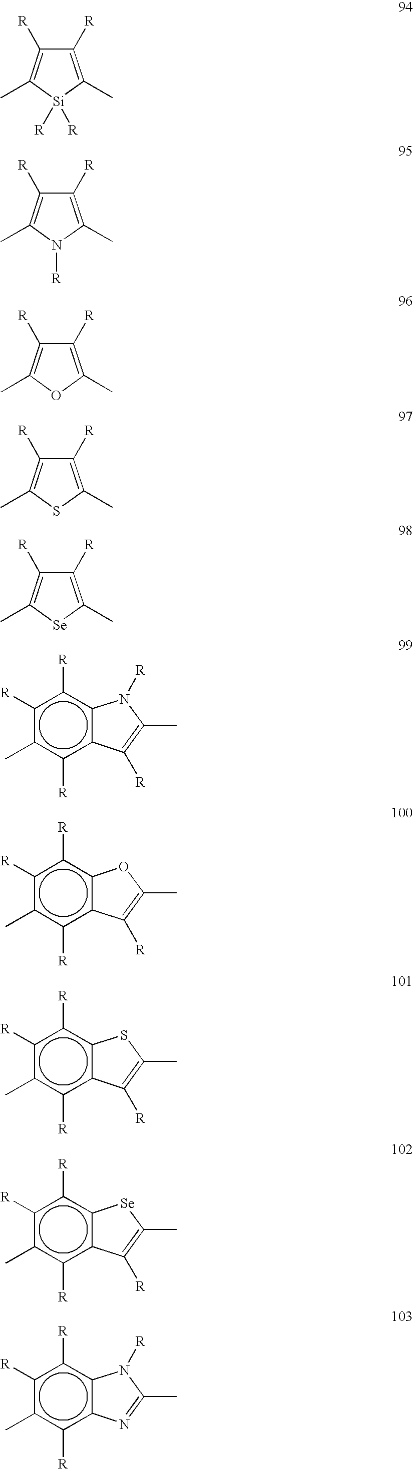

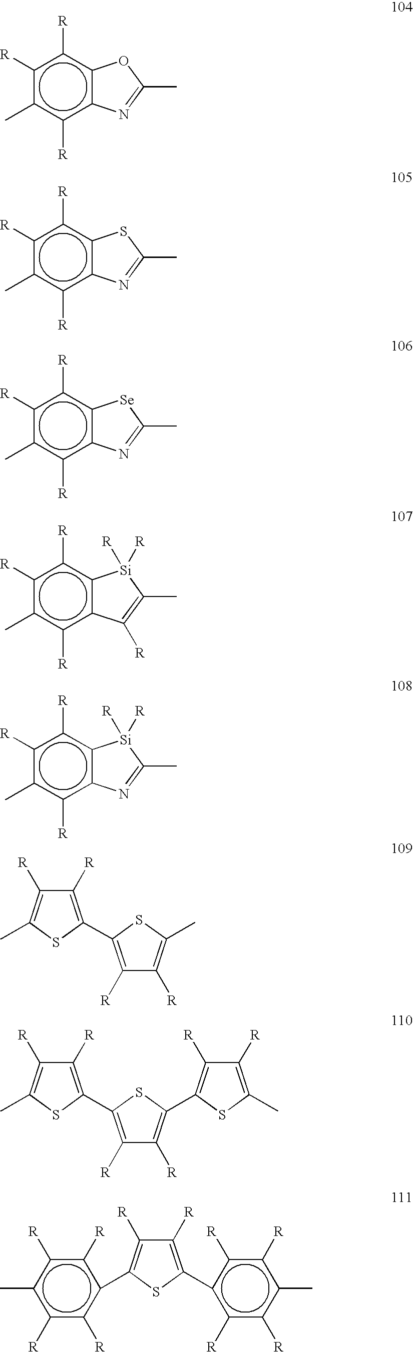

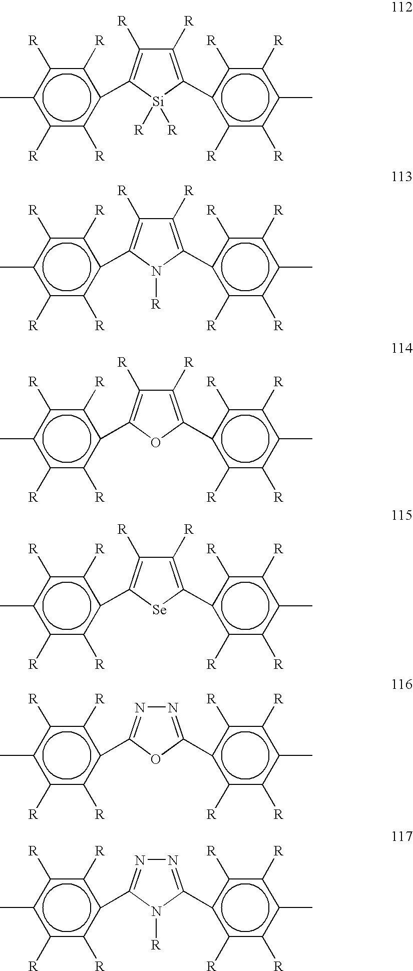

In these illustrated divalent heterocyclic groups (the above-described formulae 39 to 117), Rs are the same as those explained and illustrated (as R in the above-described formulae 1 to 38, A to I, K) in the above-described aryl group section.

In the above-described formula (1), the divalent aromatic amine group means an atomic group remaining after removal of two hydrogen atoms from an aromatic amine. The divalent aromatic amine group has a carbon number of usually about from 4 to 60 (here, the carbon number thereof does not include the carbon number of a substituent.). As the divalent aromatic amine group, for example, groups of the following general formula (3) are mentioned. Here, the formula (3) has at least one substituent of the above-described formula (2).

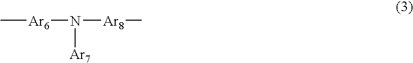

(wherein, Ar₆ and Ar₈ represent each independently an optionally substituted arylene group, a group of the following general formula (4) or a group of the following general formula (5), Ar₇ represents an optionally substituted aryl group, a group of the following general formula (6) or a group of the following general formula (7), and a ring may be formed between Ar₆ and Ar₇, Ar₆ and Ar₈, or Ar₇ and Ar₈.

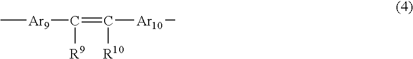

(wherein, Ar₉ and Ar₁₀ represent each independently an optionally substituted arylene group, and R⁹ and R¹⁰ represent each independently a hydrogen atom, alkyl group, aryl group, monovalent heterocyclic group or cyano group.)

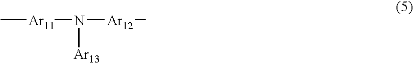

(wherein, Ar₁₁ and Ar₁₂ represent each independently an optionally substituted arylene group, Ar₁₃ represents an optionally substituted aryl group, and a ring may be formed between Ar₁₁ and Ar₁₃, Ar₁₁, and Ar₁₂, or Ar₁₂ and Ar₁₃.)

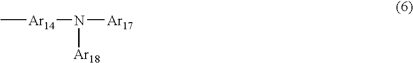

(wherein, Ar₁₄ represents an optionally substituted arylene group, Ar₁₇ and Ar₁₈ represent each independently an optionally substituted aryl group, and a ring may be formed between Ar₁₄ and Ar₁₇, Ar₁₄ and Ar₁₈, or Ar₁₇ and Ar₁₈.)

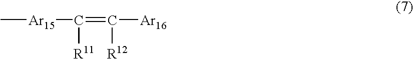

(wherein, Ar₁₅ represents an optionally substituted arylene group, Ar₁₆ represents an optionally substituted aryl group, and R¹¹ and R¹² represent each independently, a hydrogen atom, alkyl group, aryl group, monovalent heterocyclic group or cyano group.).

In the above-described formulae (3) to (7), the optionally substituted arylene groups represented by Ar₆, Ar₈ to Ar₁₂, Ar₁₄ and Ar₁₅ are the same as the arylene groups among groups explained and illustrated as Ar₁ in the above-described section of the formula (1) (here, a substituent of the above-described formula (2) may not be carried). From the standpoint of easiness of synthesis of a monomer, a phenylene group is preferable.

In the above-described formulae (3) to (7), the optionally substituted aryl groups represented by Ar₇, Ar₁₃ and Ar₁₆ to Ar₁₈ are the same as the aryl groups among groups explained and illustrated as R (in the above-described formulae 1 to 38, A to I, K) in the above-described section of the arylene group.

In the above-described formulae (3) to (7), the alkyl group, aryl group and monovalent heterocyclic group represented by R⁹ to R¹² are the same as the alkyl group, aryl group and monovalent heterocyclic group among groups explained and illustrated as R (in the above-described formulae 1 to 38, A to I, K) in the above-described section of the arylene group.

In the above-described formulae (3) to (7), Ar₆ to Ar₁₈ may have a substituent such as an alkyl group, alkoxy group, alkylthio group, alkylsilyl group, alkylamino group, aryl group, aryloxy group, arylalkyl group, arylalkoxy group, arylalkenyl group, arylalkynyl group, arylamino group, monovalent heterocyclic group, cyano group and the like.

Examples of the divalent aromatic amine group include the following groups.

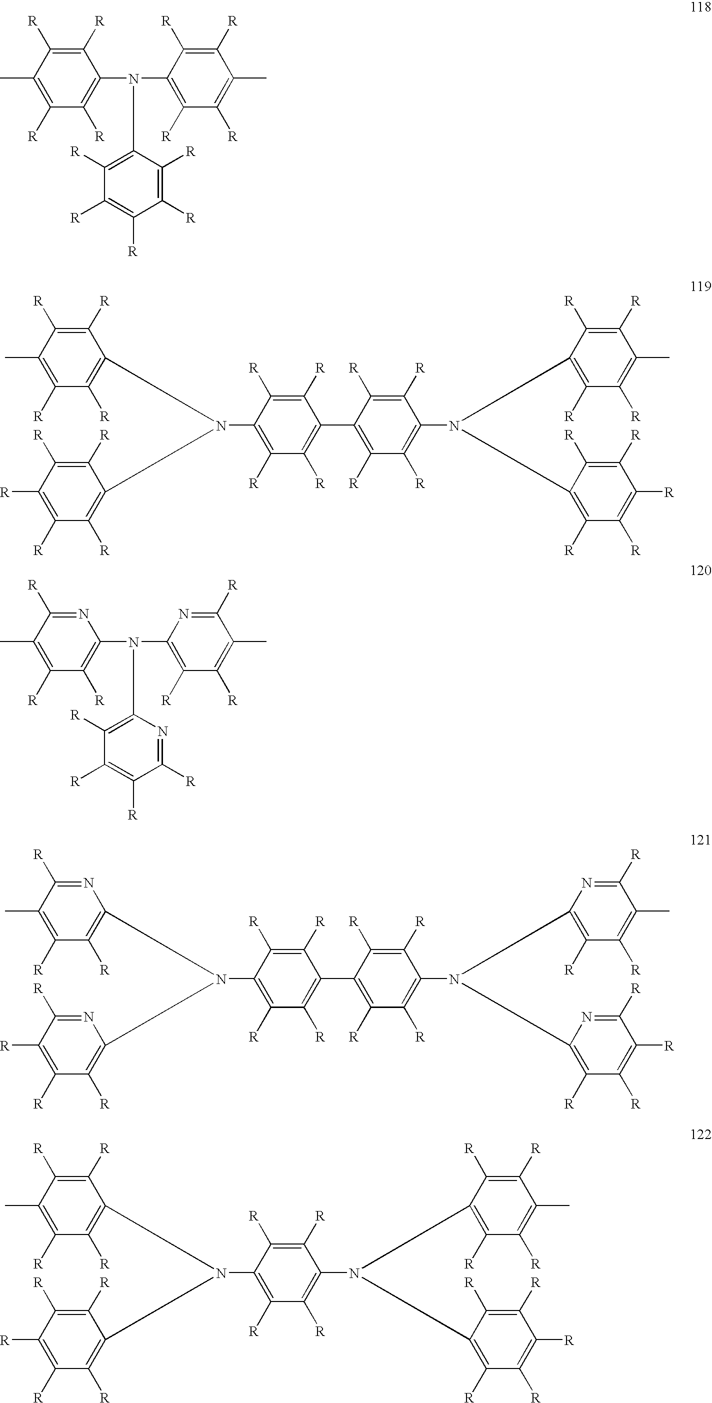

In these illustrated divalent aromatic amine groups (the above-described formulae 118 to 122), Rs are the same as those explained and illustrated (as R in the above-described formulae 1 to 38, A to I, K) in the above-described section of the arylene group.

Among the above-described Ar₁s, divalent groups of the following formula (8) and divalent groups of the following formula (9) are preferable, and divalent groups of the formula (8) are more preferable.

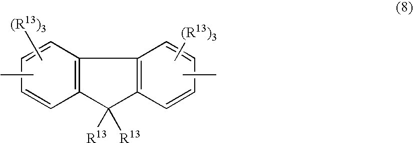

(wherein, R¹³ represents a group of the above-described formula (2), hydrogen atom, alkyl group, alkoxy group, alkylthio group, alkylsilyl group, alkylamino group, aryl group, aryloxy group, arylalkyl group, arylalkoxy group, arylalkenyl group, arylalkynyl group, arylamino group, monovalent heterocyclic group or cyano group, or, two or more of R₁₃s may be connected to form an aromatic ring or non-aromatic ring. Two or more of R₁₃s may be the same as or different from each other. Here, the formula (8) has at least one group of the above-described formula (2)).

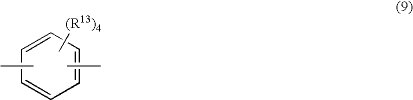

(wherein, R¹³ is the same as described above. Here, the formula (9) has at least one group of the above-described formula (2)).

From the standpoints of heat resistance, it is particularly preferable that, in the above-described formula (8), two or more of R₁₃s are connected to form an aromatic ring giving a benzofluorene-diyl group (for example, group of the above-described formulae G, H, I, K).

In the above-described formulae (8) and (9), when R₁₃s are not connected to form an aromatic ring, the groups represented by R₁₃ are specifically the same as those explained and illustrated as R (in the above-described formulae 1 to 38, A to I, K) in the above-described section of the arylene group. When R₁₃s are connected to form an aromatic ring or non-aromatic ring, the aromatic ring and non-aromatic ring may be substituted by a group of the above-described formula (2) and the like.

In the above-described formula (1), X₁ represents —CR¹═CR²— or —C≡C—, and —CR¹═CR²— is preferable from the standpoint of stability. n represents 0 or 1, and from the standpoint of photooxidation stability, 0 is preferable.

R¹ and R² represent each independently a hydrogen atom, alkyl group, aryl group, monovalent heterocyclic group or cyano group. These alkyl group, aryl group and monovalent heterocyclic group are the same as the alkyl group, aryl group and monovalent heterocyclic group among groups explained and illustrated as R (in the above-described formulae 1 to 38, A to I, K) in the above-described section of the arylene group.

In the above-described formula (2), Ar₂ is the same group as explained and illustrated as Ar₁, and Ar₂ may have no substituent of the formula (2). From the standpoint of easiness of synthesis of a monomer, Ar₂ is preferably a phenylene group.

In the above-described formula (2), Ar₅ represents a direct bond, arylene group, divalent heterocyclic group or divalent aromatic amine group. These arylene group, divalent heterocyclic group and divalent aromatic amine group are the same groups as explained and exemplified as Ar₁, and Ar₅ may have no substituent of the formula (2).

In the above-described formula (2), R³, R⁴ represent each independently a direct bond, —R⁵—, —O—R⁵—, —R⁵—O—, —R⁵—C(O)O—, —R⁵—OC(O)—, —R⁵—N(R⁶)—, —O—, —S—, —C(O)O—, —C(O)—, —CR⁷═CR⁸— or —C≡C—, R⁵ represents an alkylene group or alkenylene group, R⁶ represents a hydrogen atom, alkyl group, aryl group, monovalent heterocyclic group or cyano group. Here, when Ar₅ is a direct bond, R³ is a direct bond. Examples of the alkylene group represented by R⁵ include a methylene group, ethylene group, propylene group, butylene group, pentylene group, hexylene group, heptylene group, octylene group, 2-ethylhexylene group, nonylene group, decylene group, 3,7-dimethyloctylene group, laurylene group and the like, and preferable are a pentylene group, hexylene group, heptylene group, octylene group, 2-ethylhexylene group, nonylene group, decylene group and 3,7-dimethyloctylene group. Examples of the alkenylene group include an ethynylene group, propynylene group, butynylene group, pentynylene group, hexynylene group, heptynylene group, octynylene group, 2-ethylhexynylene group, 3,7-dimethyloctynylene group and the like. The above-described R⁷ and R⁸ represent each independently a hydrogen atom, alkyl group, aryl group, monovalent heterocyclic group or cyano group. The alkyl group, aryl group and monovalent heterocyclic group represented by R⁶, R⁷ and R⁸ are the same as the alkyl group, aryl group and monovalent heterocyclic group among groups explained and illustrated as R (in the above-described formulae 1 to 38, A to I, K) in the above-described section of the arylene group.

In the above-described formula (2), Ar₃, Ar₄ represent each independently an aryl group, monovalent heterocyclic group or monovalent aromatic amine group. Ar₃, Ar₄ may have a substituent. Examples of the substituent which can be carried on Ar₃, Ar₄ include an alkyl group, alkoxy group, alkylthio group, alkylsilyl group, alkylamino group, aryl group, aryloxy group, arylalkyl group, arylalkoxy group, arylalkenyl group, arylalkynyl group, arylamino group, monovalent heterocyclic group and the like. These substituents are specifically the same as the alkyl group, alkoxy group, alkylthio group, alkylsilyl group, alkylamino group, aryloxy group, arylalkyl group, arylalkoxy group, arylalkenyl group, arylalkynyl group and arylamino group among Rs (in the above-described formulae 1 to 38, A to I, K) explained and illustrated in the above-described section of the divalent arylene group. The aryl group and monovalent heterocyclic group are as described below.

The aryl group represented by Ar₃, Ar₄ has a carbon number of usually about from 6 to 60. Examples of this aryl group include a phenyl group, naphthyl group, anthracenyl group, biphenyl group, triphenyl group, pyrenyl group, fluorenyl group, benzofluorenyl group, stilbene-yl group, distilbene-yl group and the like. Of them, preferable are a phenyl group, naphthyl group, biphenyl group, fluorenyl group, benzofluorenyl group, stilbene-yl group and distilbene-yl group, and from the standpoint of easiness of synthesis of a monomer, a phenyl group is more preferable.

The monovalent heterocyclic group represented by Ar₃, Ar₄ means an atomic group remaining after removal of one hydrogen atom from a heterocyclic compound. This monovalent heterocyclic group has a carbon number of usually about from 2 to 60 (here, the carbon number thereof does not include the carbon number of a substituent.). The heterocyclic compound indicates organic compounds having a cyclic structure in which atoms constituting the cyclic structure include not only a carbon atom but also heteroatoms such as oxygen, sulfur, nitrogen, phosphorus, boron and the like contained in the ring. Examples of this monovalent heterocyclic group include the following groups.

a) Monovalent heterocyclic groups containing nitrogen as a heteroatom

a pyridinyl group, diazaphenyl group, quinolinyl group, quinoxalinyl group, acridinyl group, bipyridinyl group, phenanthroline-yl group and the like

b) Groups containing silicon, nitrogen, oxygen, sulfur, selenium and the like as a heteroatom and having a fluorene structure (groups of the above-described formulae 79 to 93 in which one of two connecting bonds is R)

c) 5-membered ring heterocyclic groups containing silicon, nitrogen, oxygen, sulfur, selenium and the like as a heteroatom (groups of the above-described formulae 94 to 98 in which one of two connecting bonds is R)

d) 5-membered ring condensed heterocyclic groups containing silicon, nitrogen, oxygen, sulfur, selenium and the like as a heteroatom (groups of the above-described formulae 99 to 108 in which one of two connecting bonds is R)

e) 5-membered ring heterocyclic groups containing sulfur and the like as a heteroatom, connecting at an α-position of the heteroatom to form a dimer or oligomer (groups of the above-described formulae 109 to 110 in which one of two connecting bonds is R)

f) 5-membered ring heterocyclic groups containing silicon, nitrogen, oxygen, sulfur, selenium and the like as a heteroatom, connecting at an α-position of the heteroatom to a phenyl group (groups of the above-described formulae 111 to 117 in which one of two connecting bonds is R)

Further, the monovalent heterocyclic group represented by Ar₃, Ar₄ includes also, for example, groups derived from triplet light emitting complexes, and monovalent complex groups (for example, monovalent metal complex groups as shown below, and the like) and the like are mentioned.

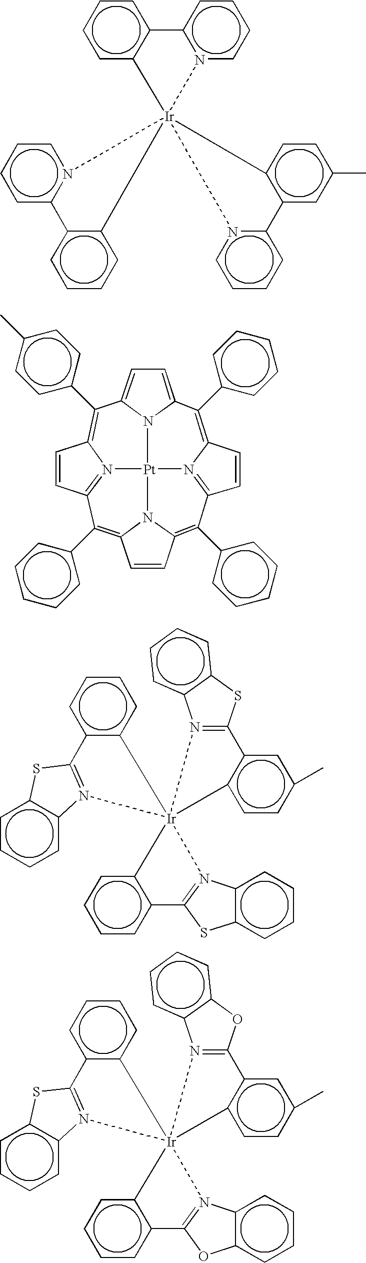

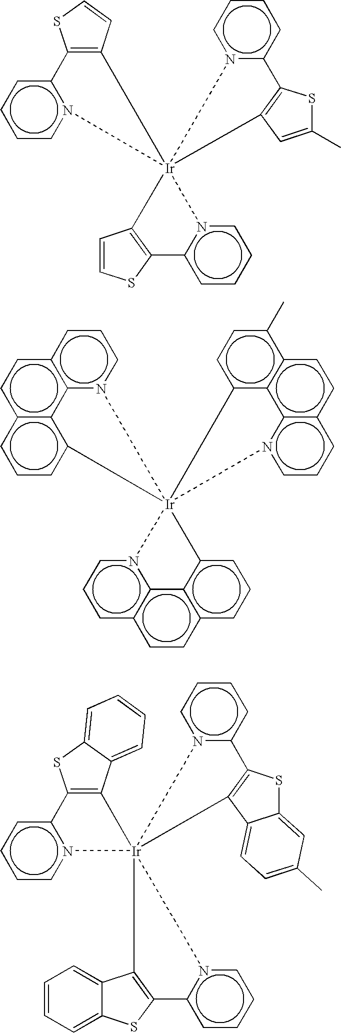

“Monovalent aromatic amine group” represented by Ar₃, Ar₄ means an atomic group remaining after removal of one hydrogen atom from an aromatic amine. This monovalent aromatic amine group has a carbon number of usually about from 4 to 60 (here, the carbon number thereof does not include the carbon number of a substituent.). Examples of this monovalent aromatic amine group include groups of the following formulae 123 to 127, and the like.

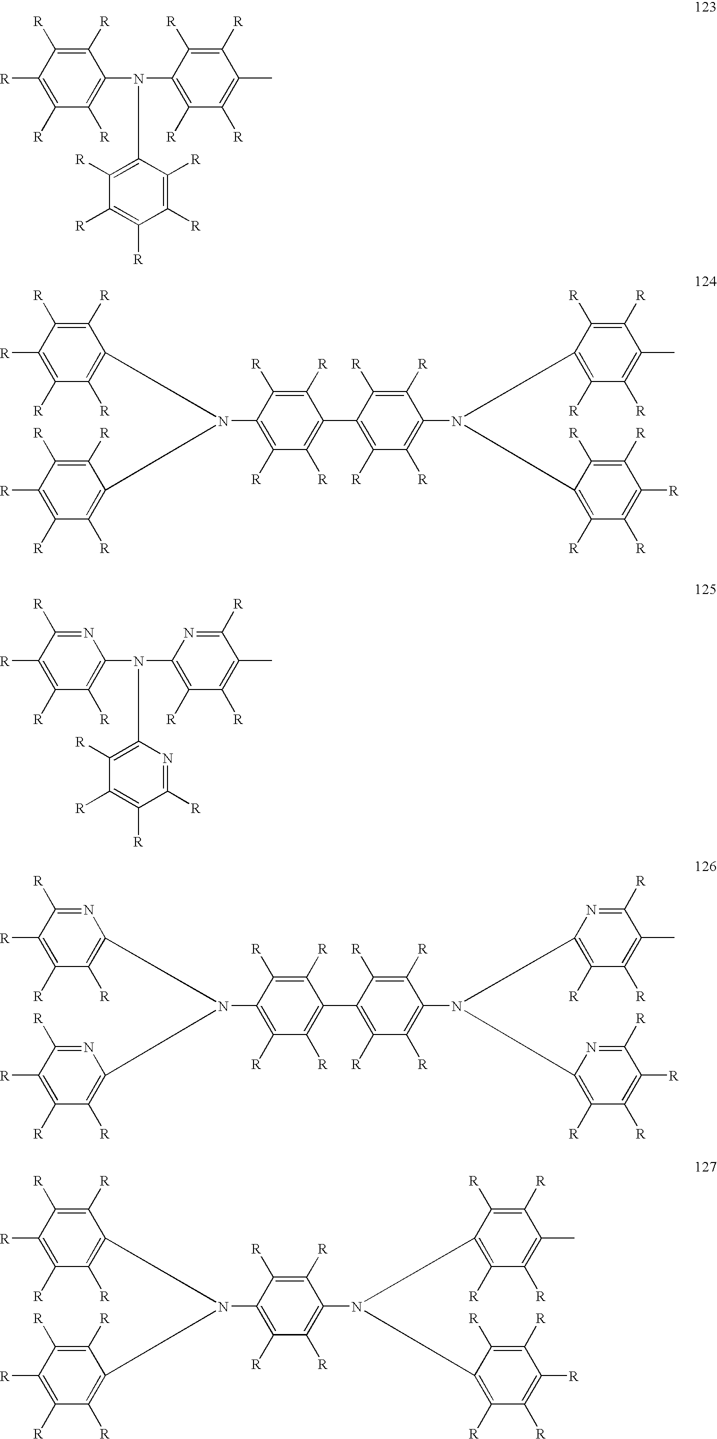

In these illustrated monovalent aromatic amine groups (the above-described formulae 123 to 127), Rs are the same as those explained and illustrated (as Rin the above-described formulae 1 to 38, A to I, K) in the above-described section of the arylene group, however, a substituent of the above-described formula (2) may not be contained.

In the above-described formula (2), Y represents the following formula:

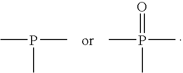

Examples of the group of the above-described formula (2) include the following groups.

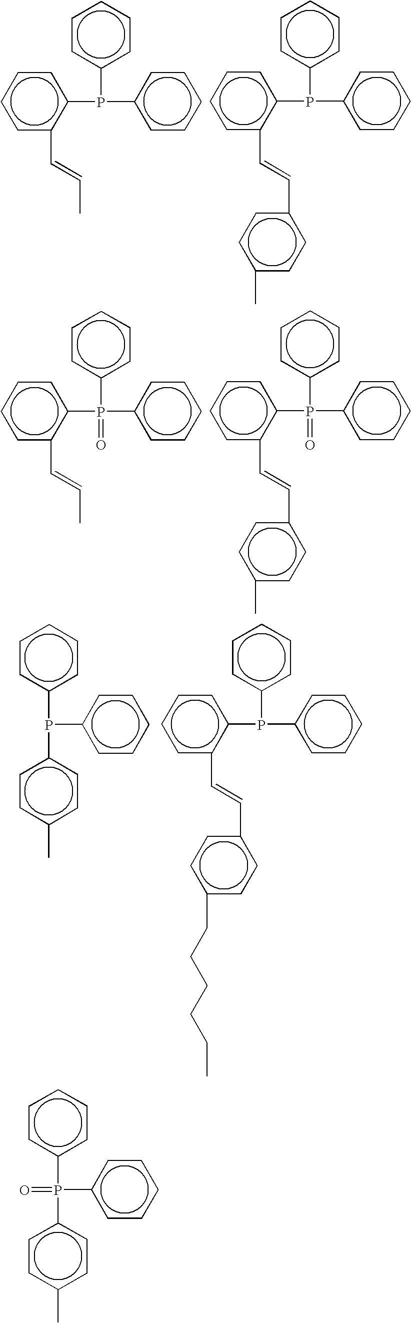

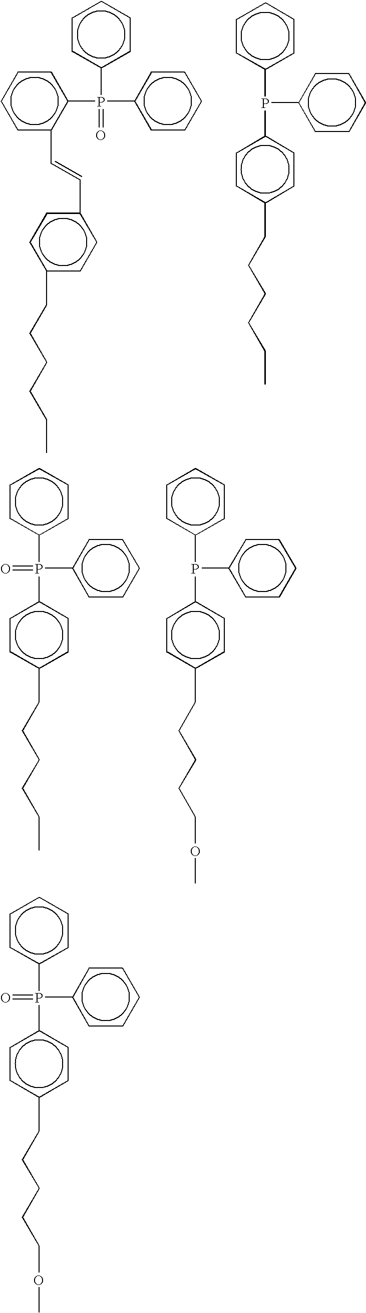

Examples of the repeating unit of the above-described formula (1) include the following units.

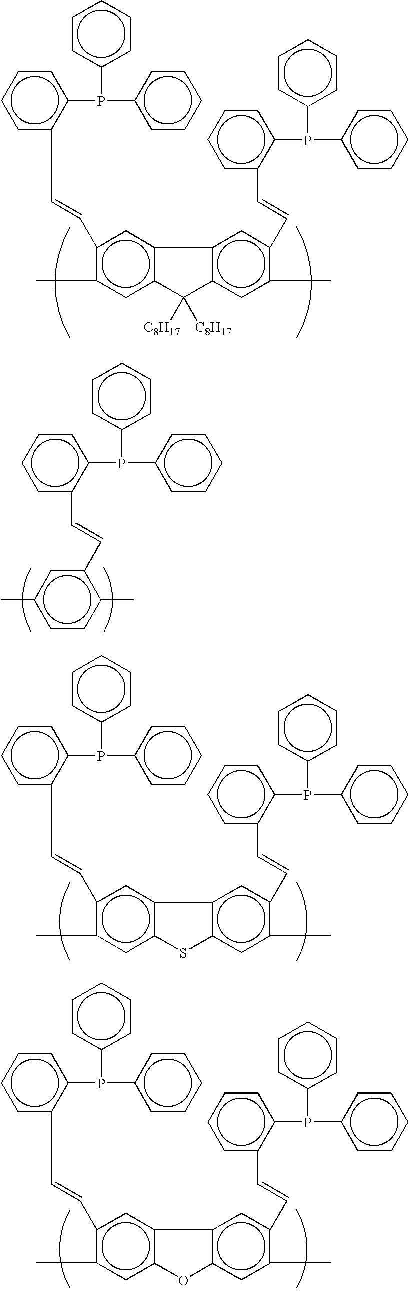

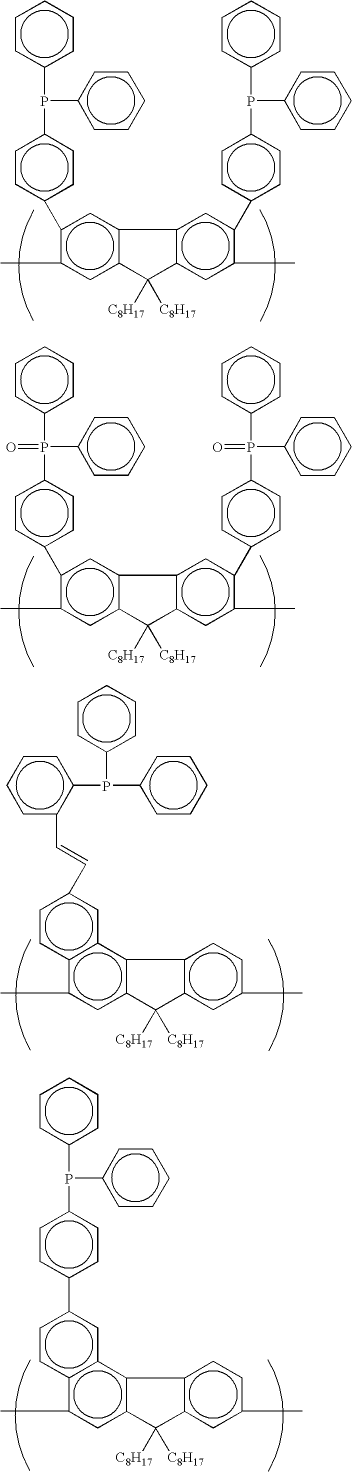

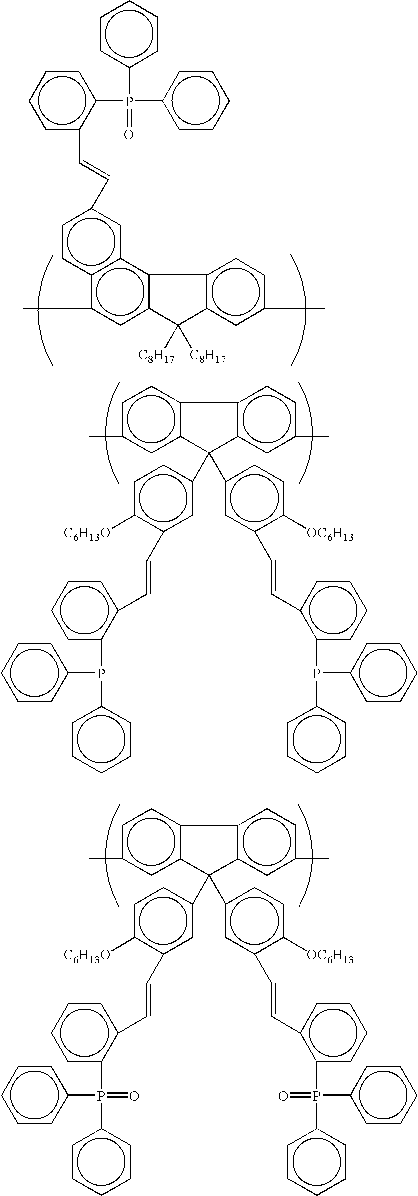

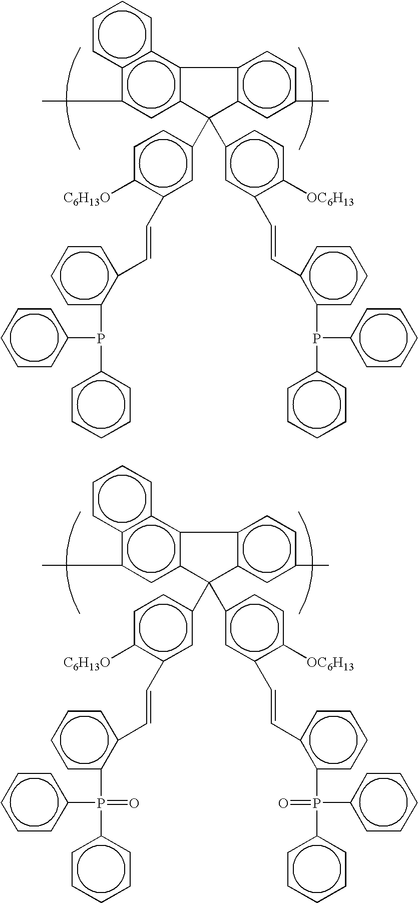

In the polymer compound of the present invention, the sum of repeating units of the above-described formula (1) is usually 1 mol % or more and 100 mol % or less with respect to all repeating units in the polymer compound. From the standpoint of the fluorescence intensity of the polymer compound, it is preferably 2 mol % or more and 50 mol % or less, more preferably 5 mol % or more and 50 mol % or less with respect to all repeating units in the polymer compound.

As the polymer compound of the present invention, those further containing a repeating unit of the following formula (10) in addition to a repeating unit of the above-described formula (1) are preferable from the standpoint of the solubility and film formability of the polymer compound.

—[Ar₁₉—(X₂)ₚ]— (10)

(wherein, Ar₁₉ represents an arylene group, divalent heterocyclic group, divalent aromatic amine group or divalent aromatic phosphine group, X₂ represents —CR¹⁴═CR¹⁵— (here, R¹⁴ and R¹⁵ represent each independently a hydrogen atom, alkyl group, aryl group, monovalent heterocyclic group or cyano group) or —C≡C—, and p represents 0 or 1.).

In the above-described formula (10), the arylene group, divalent heterocyclic group and divalent aromatic amine group represented by Ar₁₉ are the same as the groups explained and illustrated as Ar₁, and when they have a substituent, the substituent is an alkyl group, alkoxy group, alkylthio group, alkylsilyl group, alkylamino group, aryl group, aryloxy group, arylalkyl group, arylalkoxy group, arylalkenyl group, arylalkynyl group, arylamino group, monovalent heterocyclic group or cyano group. In other words, the substituent is not a substituent of the formula (2), and does not contain a phosphorus atom.

In the above-described formula (10), the divalent aromatic phosphine group represented by Ar₁₉ means an atomic group remaining after removal of two hydrogen atoms from an aromatic phosphine. The divalent aromatic phosphine group has a carbon number of usually about from 4 to 60 (here, the carbon number thereof does not include the carbon number of a substituent.). Examples of the divalent aromatic phosphine group include groups of the following formulae 200 to 203.

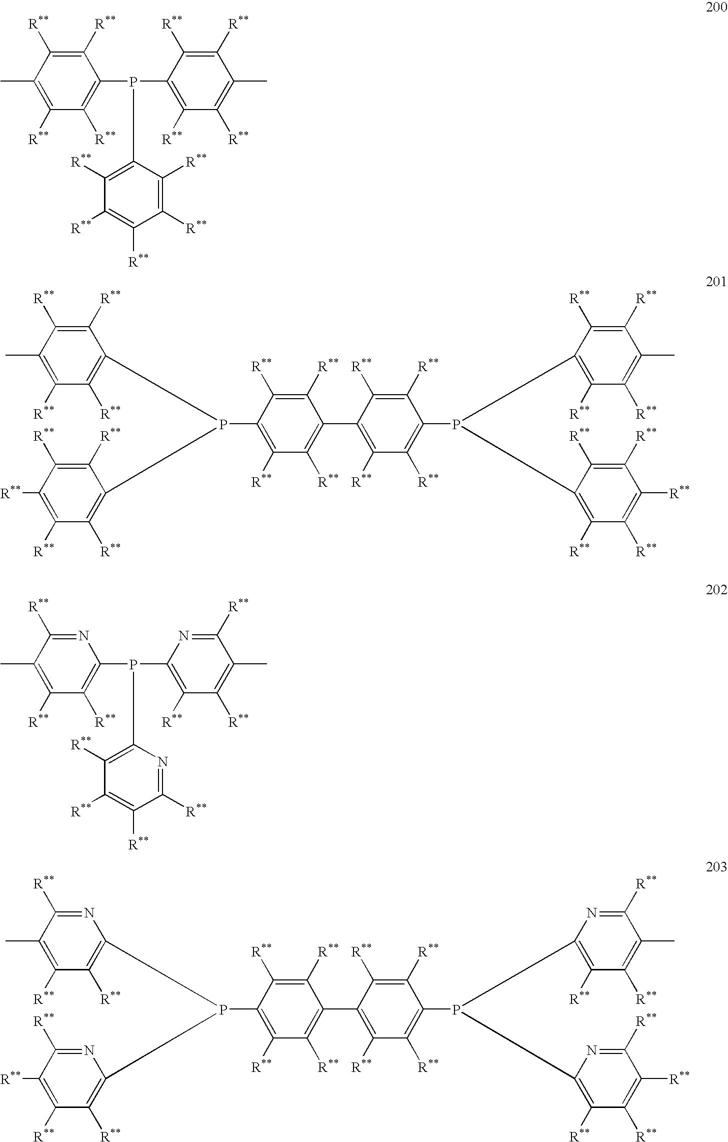

In these illustrated divalent aromatic phosphine groups (the above-described formulae 200 to 203), R**s are the same as the substituents on the arylene group, divalent heterocyclic group and divalent aromatic amine group represented by Ar₁₉. Of them, groups of the above-described formula 200 are preferable from the standpoint of easiness of synthesis of a monomer.

Ar₁₉ may have a substituent such as an alkyl group, alkoxy group, alkylthio group, alkylsilyl group, alkylamino group, aryl group, aryloxy group, arylalkyl group, arylalkoxy group, arylalkenyl group, arylalkynyl group, arylamino group, monovalent heterocyclic group and cyano group. When Ar₁₉ has a two or more of substituents, they may be the same as or different from each other. Details of these substituents are the same as those specifically explained and illustrated as R in the above-illustrated arylene groups (the above-described formulae 1 to 38, A to K), excepting groups of the above-described formula (2).

Ar₁₉ is preferably an arylene group or divalent heterocyclic group from the standpoint of the fluorescence intensity of a polymer compound. Of them, more preferable are phenylene groups, naphthalenediyl groups, biphenylene groups, fluorine-diyl groups (the above-described formulae 36 to 38), stilbene-diyl groups (the above-described formulae A to D), distilbene-diyl groups (the above-described formulae E, F), benzofluorene-diyl groups (the above-described formulae G, H, I, K), groups containing silicon, nitrogen, oxygen, sulfur, selenium and the like as a heteroatom and having a fluorene structure (the above-described formulae 79 to 93), 5-membered ring heterocyclic groups containing sulfur and the like as a heteroatom, connecting at an α-position of the heteroatom to form a dimer or oligomer (the above-described formulae 109 to 110), and 5-membered ring heterocyclic groups containing silicon, nitrogen, oxygen, sulfur, selenium and the like as a heteroatom, connecting at an α-position of the heteroatom to a phenyl group (the above-described formulae III to 117).

Among the above-described Ar₁₉s, divalent groups of the following formulae (2a) to (2d) are more preferable from the standpoint of the heat resistance and fluorescence intensity of a polymer compound.

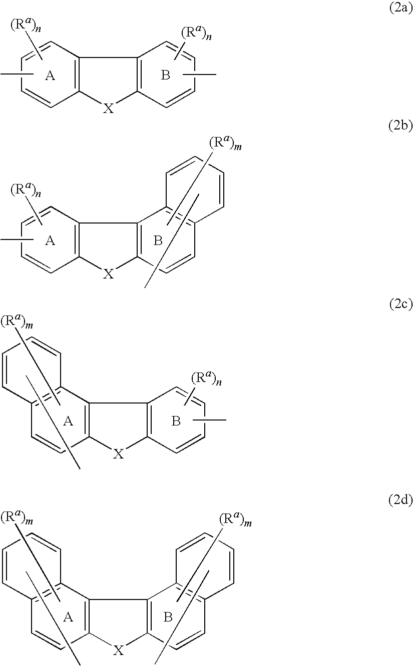

(wherein, X represents an atom or divalent group forming a 5-membered ring or 6-membered ring together with two atoms on a ring A and two atoms on a ring B, R^{a} represents a substituent, m's represent independently an integer of 0 to 5, and n's represent independently an integer of 0 to 3. When there are two or more of R^{a}s, they may be the same or different.).

In the above-described formulae (2a) to (2d), the atom and divalent group represented by X include, for example, —C(R¹⁸)(R¹⁹)—, —C(R²⁰)(R²¹)—C(R²²)(R²)—, —, —S—, —SO₂—, —Se—, —Te—, —N(R²⁴)—, —Si(R²⁵) (R²⁶)— and the like, and preferable from the standpoint of easiness of synthesis of a polymer compound and the fluorescence intensity thereof are —C(R¹⁸)(R¹⁹)—, —C(R²⁰)(R²¹)—C(R²²)(R²³)—, —O—, —S— and —N(R²⁴)— Here, R¹⁸, R¹⁹, R²⁰, R²¹, R²² and R²³ represent each independently a hydrogen atom, alkyl group, alkoxy group, alkylthio group, alkylsilyl group, alkylamino group, aryl group, aryloxy group, arylalkyl group, arylalkoxy group, arylalkenyl group, arylalkynyl group, arylamino group, monovalent heterocyclic group or cyano group. These groups are the same as those explained and illustrated (as R in the above-described formulae 1 to 38, A to I, K) in the above-described section of the arylene group. Here, a substituent of the formula (2) is not contained. R²⁴, R²⁵ and R²⁶ represent each independently a hydrogen atom, alkyl group, aryl group, arylalkyl group or monovalent heterocyclic group. Here, the alkyl group, aryl group, arylalkyl group and monovalent heterocyclic group represented by R²⁴, R²⁵ and R²⁶ are the same as those explained and illustrated (as R in the above-described formulae 1 to 38, A to I, K) in the above-described section of the arylene group.

In the above-described formulae (2a) to (2d), the substituents represented by R^{a} are the same as those explained and illustrated (as R in the above-described formulae 1 to 38, A to I, K) in the above-described section of the arylene group. Here, a substituent of the formula (2) is not contained.

Examples of repeating units of the above-described formulae (2a) to (2d) include the following groups.

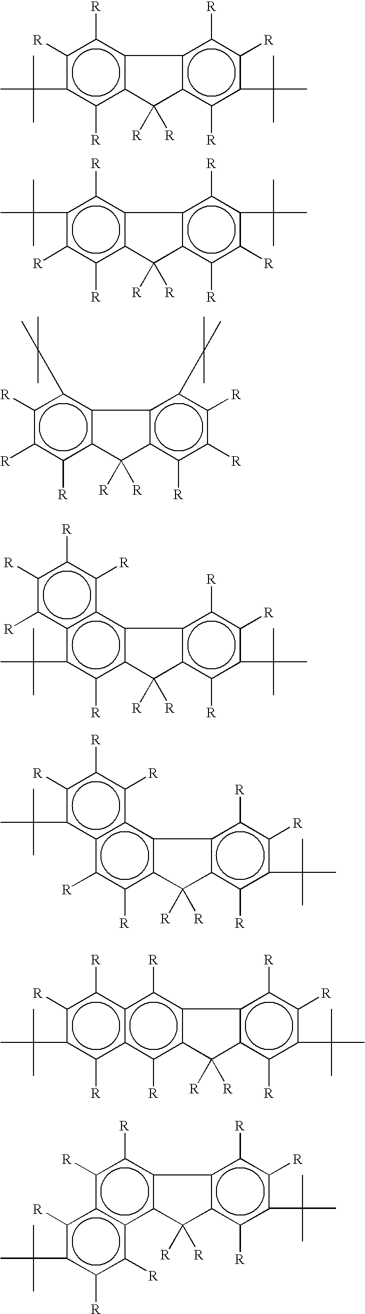

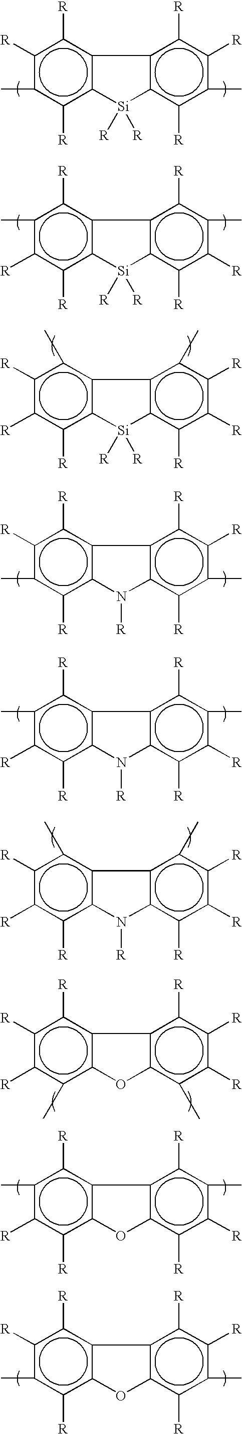

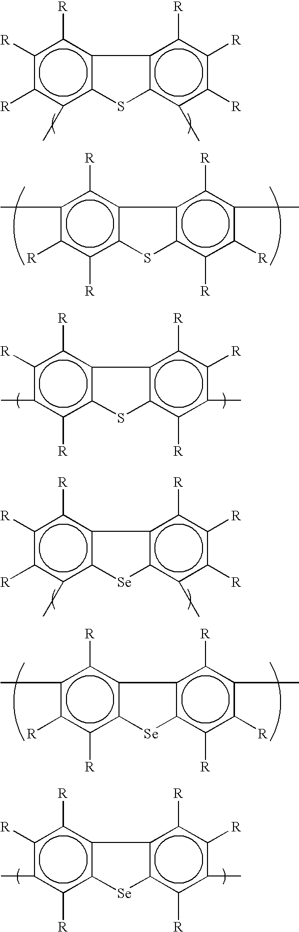

(wherein, R is as described above. R is not a group of the above-described formula (2)).

The following groups are preferable from the standpoint of the fluorescence intensity of a polymer compound.

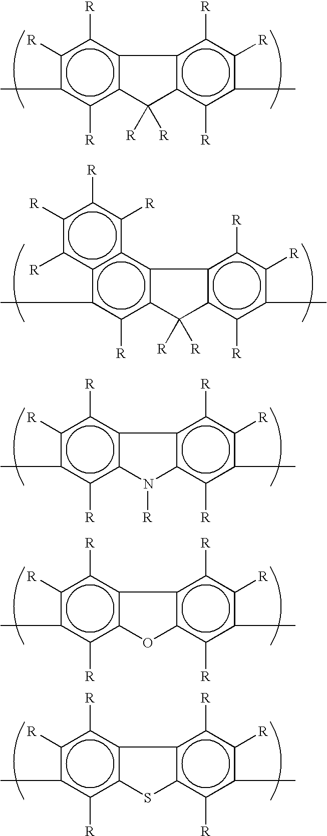

(wherein, R is as described above. R is not a group of the above-described formula (2)).

Of them, the following groups are particularly preferable.

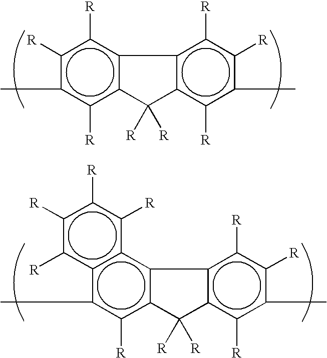

(wherein, R is as described above. R is not a group of the above-described formula (2)).

In the above-described formulae, two or more of Rs are present in one structural formula, and they may be the same or different. In the above-described formulae, the groups represented by R are the same as those explained and illustrated (as R in the above-described formulae 1 to 38, A to I, K) in the above-described section of the arylene group. Here, a substituent of the above-described formula (2) is not contained.

In the above-described formula (10), X₂ represents —CR¹⁴═CR¹⁵— or —C≡C—, and —CR¹⁴═CR¹⁵— is preferable from the standpoint of stability.

R¹⁴ and R¹⁵ represent each independently a hydrogen atom, alkyl group, aryl group, monovalent heterocyclic group or cyano group. p represents 0 or 1. It is preferable that p is 0 from the standpoint of the photooxidation stability of a polymer compound. R¹⁴ and R¹⁵ are the same as those explained and illustrated for the above-described R¹ and R².

The polymer compound of the present invention may contain a repeating unit other than the repeating unit of the above-described formula (1) and the repeating unit of the above-described formula (10), in a range not deteriorating the fluorescence intensity and charge transporting property.

In a preferable embodiment of the present invention, the polymer compound has essentially a repeating unit of the above-described formula (1) and a repeating unit of the above-described formula (10). Here, “has essentially” means that the sum of a repeating unit of the above-described formula (1) and a repeating unit of the above-described formula (10) is 50 to 100 mol %, preferably 80 to 100 mol %, more preferably 90 to 100 mol % with respect to all repeating units in the polymer compound of the present invention.

Examples of the polymer compound according to this preferable embodiment include copolymers composed of one or more selected from the following formulae as the repeating unit of the above-described formula (1):

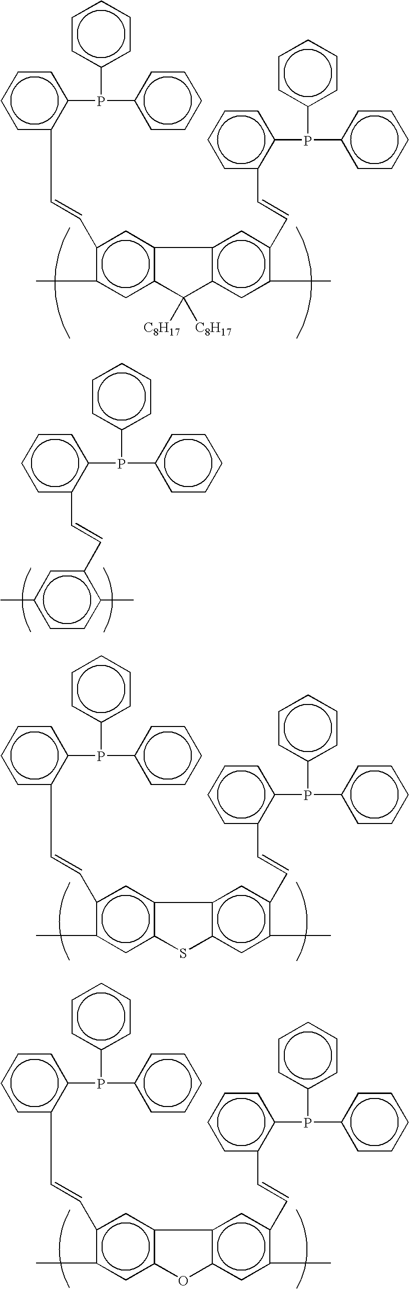

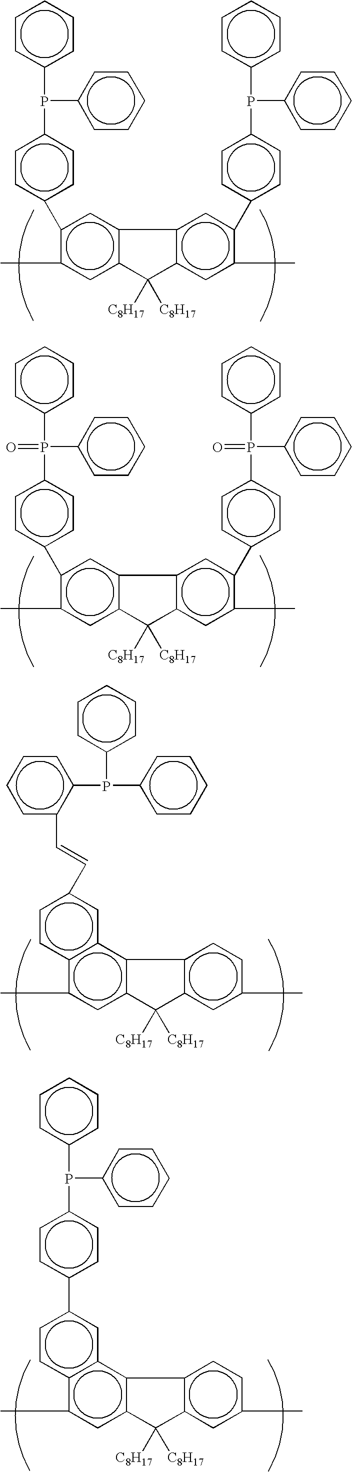

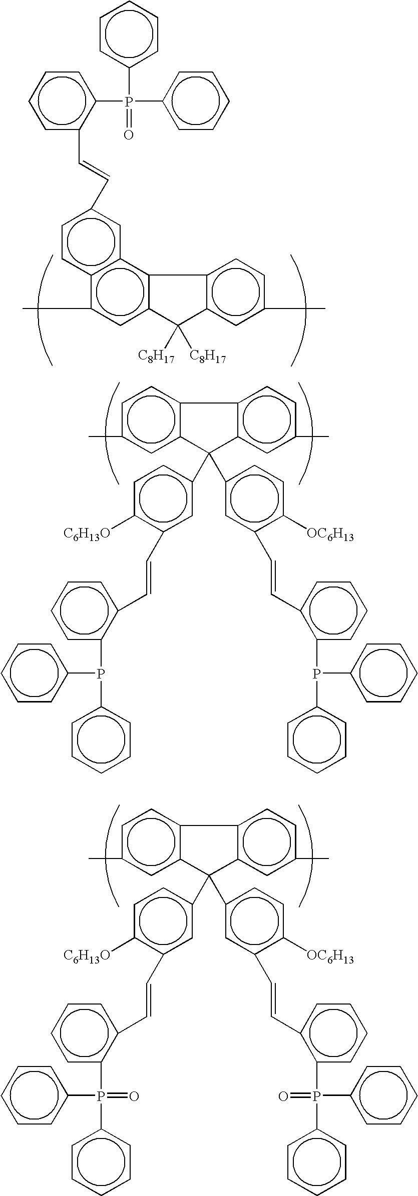

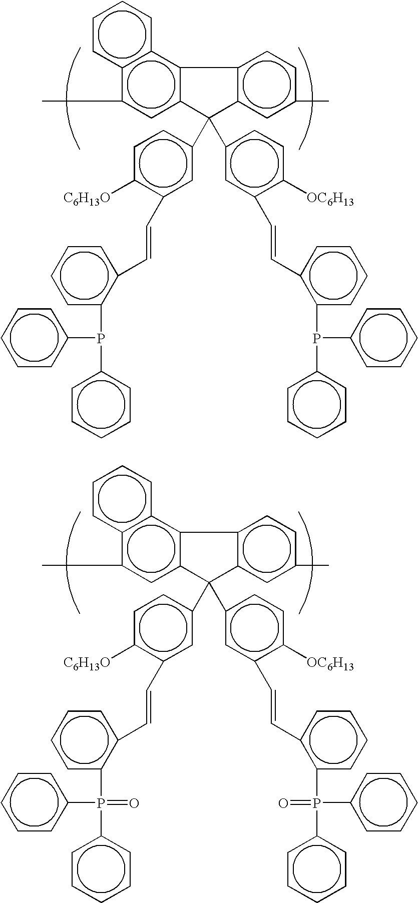

and one or more selected from the following formulae as the repeating unit of the above-described formula (10):

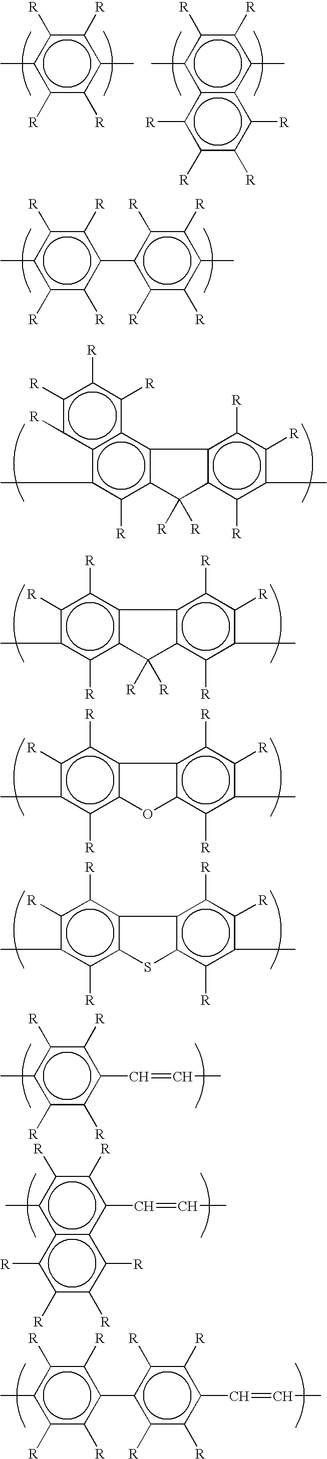

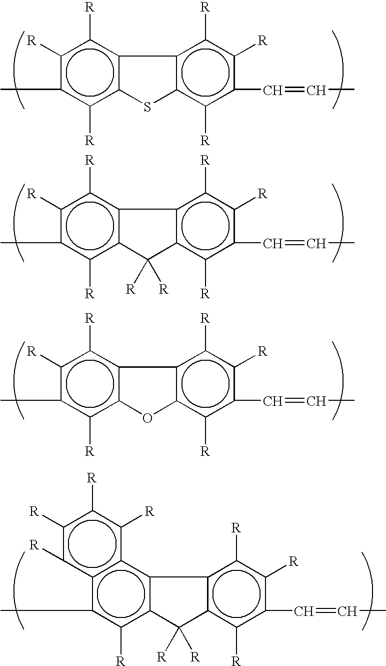

In these examples having essentially a repeating unit of the formula (1) and a repeating unit of the formula (10), Rs are the same as those explained and illustrated as R (in the above-described formulae 1 to 38, A to I, K) in the above-described section of the arylene group (here, Rs as illustrated as the repeating unit of the above-described formula (10) dot not include a substituent of the above-described formula (2)).

Among polymer compounds containing a repeating unit of the above-described formula (1) and a repeating unit of the above-described formula (10), more preferable from the standpoint of heat resistance are those in which the sum of a repeating unit of the above-described formula (1) and a repeating unit of the above-described formula (10) is 50 mol % or more based on all repeating units in the polymer compound and the amount of a repeating unit of the above-described formula (1) is 2 mol % or more and 90 mol % or less with respect to the sum of a repeating unit of the above-described formula (1) and a repeating unit of the above-described formula (10).

### —Feature of Polymer Compound—

The polymer compound of the present invention has a polystyrene-reduced number average molecular weight of preferably 1×10³ to 1×10⁸, more preferably 2×10³ to 1×10⁷. The polymer compound of the present invention preferably shows fluorescence and/or phosphorescence at solid state.

When a group participating in polymerization (usually, called polymerization active group) remains on a group at the molecular chain end (namely, end group) in the polymer compound of the present invention, there is a possibility of lowering of light emitting property and life when the polymer compound is used in a light emitting device, thus, it may be protected by a stable group not participating in polymerization. As this end group, those having a conjugated bond consecutive to a substantial conjugation structure of the molecule main chain are preferable. For example, structures connected to an aryl group or heterocyclic group via a vinylene group may be permissible. Specifically, substituents described in chemical formula 10 of Japanese Patent Application Laid-Open (JP-A) No. 9-45478 and the like are illustrated.

The polymer compound of the present invention usually has a molecule main chain of substantially conjugation type. In the present specification, “of substantially conjugation type” means that repeating units in an amount of usually 50 to 100 mol %, preferably 80 to 100 mol %, more preferably 90 to 100 mol % based on all repeating units constituting the molecule main chain constitute the conjugation system of the molecule main chain.

Repeating units may be connected via a vinylene group or nonconjugated portion, or repeating units may contain a vinylene group or nonconjugated portion. As the connected structure containing the above-described nonconjugated portion, illustrated are those shown later, combinations of those shown later with a vinylene group, and combinations of two or more of those shown below, and the like.

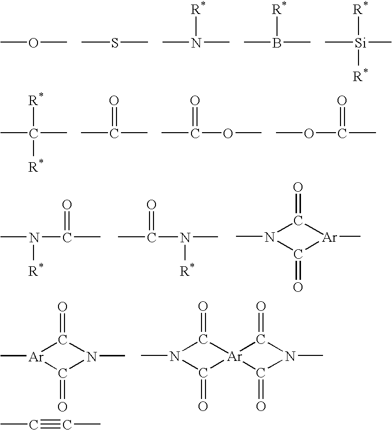

In these illustrated connected structures containing a nonconjugated portion, R* represents the same group as R′. Ar represents a hydrocarbon group having a carbon number of 6 to 60 (specifically, groups containing a hydrogen atom as a connecting bond such as, for example, benzene, biphenyl, terphenyl, naphthalene, anthracene and the like).

The polymer compound of the present invention may be a random copolymer, block copolymer or graft copolymer, or a polymer having an intermediate structure, for example, a random copolymer having a block property. From the standpoint of obtaining a polymer compound having high fluorescence intensity, a random copolymer having a block property and a block or graft copolymer are more preferable than a complete random copolymer. The polymer compound of the present invention includes also those having branching in the main chain and thus having 3 or more end parts, and dendrimers and the like.

The polymer compound of the present invention can be dissolved partially or totally, or dispersed in a solvent, if necessary. As the good solvent for the polymer compound of the present invention, chloroform, methylene chloride, dichloroethane, tetrahydrofuran, toluene, xylene, mesitylene, tetralin, decalin, n-butylbenzene and the like are illustrated. Depending on the structure and molecular weight of the polymer compound, the polymer compound can be dissolved usually in an amount of 0.1 wt % or more in these solvents.

### —Production Method of Polymer Compound—

Next, the production method of the polymer compound of the present invention will be explained in a case (i) wherein the polymer compound has a vinylene group in the main chain (namely, n=1 in the above-described formulae (1)) and in a case (ii) wherein the polymer compound has no vinylene group (namely, n=0 in the above-described formula (1)).

(i) As the production method when the polymer compound of the present invention has a vinylene group in the main chain, for example, methods described in JP-A No. 5-202355 are mentioned. That is, methods such as polymerization by the Wittig reaction of a compound having an aldehyde group and a compound having a phosphonium salt group, or of a compound having an aldehyde group and a phosphonium salt group, polymerization by the Heck reaction of a compound having a vinyl group and a compound having a halogen atom, or of a compound having a vinyl group and a halogen group, polymerization by the Horner-Wadsworth-Emmons method of a compound having an aldehyde group and a compound having an alkyl phosphonate group, of a compound having an aldehyde group and an alkyl phosphonate group, polycondensation by the dehydrohalogenation method of a compound having two or more methyl halide groups, polycondensation by the sulfonium salt decomposition method of a compound having two or more sulfonium salt groups, polymerization by the Knoevenagel reaction of a compound having an aldehyde group and a compound having an acetonitrile group, or of a compound having an aldehyde group and an acetonitrile group, and the like, methods such as polymerization by the McMurry reaction of a compound having two or more aldehyde groups, and the like, are illustrated. These reactions are preferably carried out under an inert atmosphere such as a nitrogen gas, argon gas and the like.

(ii) When the main chain carries no vinylene group, for example, a method of polymerization by the Suzuki coupling reaction from the correspondent monomer, a method of polymerization by the Grignard reaction, a method of polymerization with a Ni(0) catalyst, a method of polymerization with an oxidizer such as FeCl₃ and the like, a method of electrochemical oxidation polymerization, a method by decomposition of an intermediate polymer having a suitable leaving group, and the like, are illustrated. These reactions are preferably carried out under an inert atmosphere such as a nitrogen gas, argon gas and the like.

Among them, the methods of polymerization by the Wittig reaction, polymerization by the Heck reaction, polymerization by the Horner-Wadsworth-Emmons method, polymerization by the Knoevenagel reaction and polymerization by the Suzuki coupling reaction, the method of polymerization by the Grignard reaction, and the method of polymerization with a Ni(0) catalyst are preferable since structure control is easier.

Specifically, a compound having two or morereaction active groups as a monomer can be, if necessary, dissolved in an organic solvent, and reacted at a temperature not lower than the melting point and not higher than the boiling point of the organic solvent using, for example, an alkali or suitable catalyst. Known methods described in, for example, “Organic Reactions”, vol. 14, p. 270 to 490, John Wiley & Sons, Inc., 1965, “Organic Reactions”, vol. 27, p. 345 to 390, John Wiley & Sons, Inc., 1982, “Organic Syntheses”, Collective Volume VI, p. 407 to 411, John Wiley & Sons, Inc., 1988, Chem. Rev., vol. 95, p. 2457 (1995), J. Organomet. Chem., vol. 576, p. 147 (1999), J. Prakt. Chem. vol. 336, p. 247 (1994), Makromol. Chem., Macromol. Symp., vol. 12, p. 229 (1987), and the like can be used.

The kind of the organic solvent varies with the compound and reaction to be used. In general, for suppressing a side reaction, it is preferable that the organic solvent to be used is subjected to a sufficient deoxidation treatment, and the reaction is progressed under an inert atmosphere. Further, it is preferable to carry out a dehydration treatment likewise (here, it is not applicable in the case of a reaction in a two-phase system with water such as the Suzuki coupling reaction).

For promoting the reaction, an alkali and a suitable catalyst are added appropriately. These may be advantageously selected depending on the reaction to be used. As these alkali and catalyst, those which are sufficiently dissolved in the solvent to be used in the reaction are preferable. As the method of mixing an alkali and a catalyst, illustrateded is a method in which a solution of an alkali and a catalyst is added slowly while stirring the reaction liquid under an inert atmosphere such as argon, nitrogen and the like, or a method in which the reaction liquid is added slowly to a solution of an alkali and a catalyst.

More specifically, in the case of the Wittig reaction, Horner reaction, Knoevenagel reaction and the like, the reaction is effected using an alkali in an amount of equivalent or more, preferably 1 to 3 equivalents with respect to the reaction active group of a monomer. The alkali is not particularly restricted, and for example, potassium t-butoxide, sodium t-butoxide, metal alcoholates such as sodium ethylate, lithium methylate and the like, hydride reagents such as sodium hydride and the like, amides such as sodium amide and the like, can be used. As the solvent, N,N-dimethylformamide, tetrahydrofuran, dioxane, toluene and the like are used. The reaction can be progressed at a reaction temperature usually from room temperature to around 150° C. The reaction time is, for example, from 5 minutes to 40 hours, and times for sufficient progress of polymerization may be permissible, and there is no necessity to be left for a long time after completion of the reaction, thus, the reaction time is preferably from 10 minutes to 24 hours. When the concentration in the reaction is too low, the reaction efficiency is poor and when too high, control of the reaction is difficult, thus, the concentration may be appropriately selected in a range from about from 0.01 wt % to dissolvable maximum concentration, and usually in a range from 0.1 wt % to 20 wt %.

In the case of the Heck reaction, a monomer is reacted using a palladium catalyst in the presence of a base such as triethylamine and the like. A solvent having relatively high boiling point such as N,N-dimethylformamide, N-methylpyrrolidone and the like is used, the reaction temperature is about from 80 to 160° C., and the reaction time is about from 1 hour to 100 hours.

In the case of the Suzuki coupling, for example, palladium[tetrakis(triphenylphosphine)], palladium acetates and the like are used as a catalyst, and in organic bases such as potassium carbonate, sodium carbonate, barium hydroxide and the like, organic bases such as triethylamine and the like, and inorganic salts such as cesium fluoride and the like are added in an amount of equivalent or more, preferably 1 to 10 equivalents with respect to a monomer, and they are reacted. It may also be permissible that an inorganic salt is used in the form of aqueous solution and reacted in a two-phase system. As the solvent, N,N-dimethylformamide, toluene, dimethoxyethane, tetrahydrofuran and the like are illustrated. Depending on the solvent, temperatures of about from 50 to 160° C. are suitably selected. The temperature may be raised up to around boiling point of the solvent, to cause reflux. The reaction time is from about 1 hour to 200 hours.

In the case of the Grignard reaction, a method is illustrated in which a halide and metal Mg are reacted in an ether solvent such as tetrahydrofuran, diethyl ether, dimethoxyethane and the like to give a Grignard reagent solution which is mixed with a monomer solution prepared separately, and a nickel or palladium catalyst is added while noticing an excess reaction, then, the temperature is raised and the mixture is reacted under reflux. The Grignard reagent is used in an amount of equivalent, preferably 1 to 1.5 equivalents, more preferably 1 to 1.2 equivalents with respect to a monomer. In the case of polymerization by a method other than these methods, the reaction can be carried out according to known methods.

In the case of use of a zero-valent nickel complex, a method is illustrated in which a halide is reacted using a zero-valent nickel complex in N,N-dimethylformamide, N,N-dimethylacetamide, and an ether solvent such as tetrahydrofuran, 1,4-dioxane and the like, and an aromatic hydrocarbon solvent such as toluene and the like. As the zero-valent nickel complex, bis(1,5-cyclooctadiene)nickel(0), (ethylene)bis(triphenylphosphine)nickel(0), tetrakis(triphenylphosphine)nickel and the like are illustrated, and bis(1,5-cyclooctadiene)nickel(0) is preferable.

In the case of use of a zerovalent nickel complex, it is preferable to add a compound acting as a neutral ligand from the standpoint of improvement in the yield of a polymer compound and increase in the molecular weight thereof. The neutral ligand is a ligand not having anion and cation. Examples of the compound acting as a neutral ligand include compounds acting as a nitrogen-containing ligand such as 2,2′-bipyridyl, 1,10-phenanthroline, methylenebisoxazoline, N,N′-tetramethylethylenediamine and the like; compounds acting as a tertiary phosphine ligand such as triphenylphosphine, tritolylphosphine, tributylphosphine, triphenoxyphosphine, and the like, and preferable from the standpoint of general versatility and cheapness are compounds acting as a nitrogen-containing ligand, and 2,2′-bipyridyl is particularly preferable from the standpoint of high reactivity and high yield.

In particular, a system obtained by adding 2,2′-bipyridyl as the compound acting as a neutral ligand to a system containing bis(1,5-cyclooctadiene)nickel(0) is preferable from the standpoint of increase in the molecular weight of a polymer.

The use amount of a zero-valent nickel complex is not particularly restricted providing it does not disturb the polymerization reaction, and when it is too small, the polymerization reaction time becomes longer, while when too large, a post treatment is difficult, thus, the use amount thereof is 0.1 mol or more, preferably 1 mol or more with respect to 1 mol of a monomer. When the use amount is too small, the molecular weight tends to be small. Though the upper limit thereof is not restricted, if the use amount is too large, a post treatment tends to be difficult, thus, the use amount is preferably 5.0 mol or less.

In the case of use of the compound acting as a neutral ligand, the use amount thereof is usually about from 0.5 to 10 mol with respect to 1 mol of a zero-valent nickel complex, and from the standpoint of cost performance (high yield and cheap charge), it is preferably 0.9 mol to 1.1 mol. In the case of polymerization by a method other than these methods, the reaction can be effected according to known method.

A method of polymerization with a Ni(0) catalyst is particularly preferable because of easier availability of raw materials and simplicity of the polymerization reaction operation.

### —Light Emitting Material—

The polymer compound of the present invention is useful as a light emitting material. That is, the light emitting material of the present invention contains the above-described polymer compound. In this light emitting material, components other than the above-described polymer compound (for example, light emitting materials other than the above-described polymer compound, hole transporting materials, electron transporting materials, and the like) may be compounded if necessary.

### —Application of Polymer Compound—

The polymer compound of the present invention is useful as, for example, an organic semiconductor material, optical material and the like, in addition to light emitting materials. Further, it can also be used as an electrical conductive material by doping.

In the case of use of the polymer compound of the present invention as a light emitting material (for example, light emitting material of polymer light emitting device), its purity exerts an influence on a light emitting property, thus, it is preferable that a monomer before polymerization is purified by a method such as distillation, sublimation purification, re-crystallization and the like before performing polymerization, and after synthesis, a refinement treatment such as reprecipitation purification, chromatography fractionation and the like is preferably carried out.

### <Liquid Composition>

The liquid composition of the present invention contains the above-described polymer compound and a solvent. This liquid composition may contain a polymer compound of the present invention, and examples thereof include poly(phenylene) and derivatives thereof, poly(fluorene) and derivatives thereof, poly(benzofluorene) and derivatives thereof, poly(dibenzofuran) and derivatives thereof, poly(dibenzothiophene) and derivatives thereof, poly(carbazole) and derivatives thereof, poly(thiophene) and derivatives thereof, poly(phenylenevinylene) and derivatives thereof, poly(fluorenevinylene) and derivatives thereof, poly(benzofluorenevinylene) and derivatives thereof, poly(dibenzofuranvinylene) and derivatives thereof, and the like.

The liquid composition of the present invention is useful for manufacturing of an organic transistors and a light emitting device such as polymer light emitting devices and the like. In this specification, “liquid composition” means a composition which is liquid in device production, and typically, one which is liquid at normal pressure (namely, 1 atm) and 25° C. The liquid composition is, in general, referred to as ink, ink composition, solution or the like in some cases.

The liquid composition of the present invention may contain a low molecular weight light emitting material, hole transporting material, electron transporting material, stabilizer, additives for controlling viscosity and/or surface tension, antioxidant and the like, in addition to the above-described polymer compound. These optional components may be used each singly or in combination of two or more.

Examples of the low molecular weight light emitting material which may be contained in the liquid composition of the present invention include light emitting materials of low molecular weight such as naphthalene derivatives, anthracene, anthracene derivatives, perylene, perylene derivatives, polymethine coloring matters, xanthene coloring matters, coumarin coloring matters, cyanine coloring matters, metal complexes having a metal complex of 8-hydroxyquinoline as a ligand, metal complexes having a 8-hydroxyquinoline derivative as a ligand, other light emitting metal complexes, aromatic amines, tetraphenylcyclopentadiene, tetraphenylcyclopentadiene derivatives, tetraphenylcyclobutadiene, tetraphenylcyclobutadiene derivatives, stilbenes, silicon-containing aromatics, oxazoles, furoxans, thiazoles, tetraarylmethanes, thiadiazoles, pyrazoles, metacyclophanes, acetylenes and the like. Examples thereof include those described in JP-A Nos. 57-51781, 59-194393 and the like, and known materials.

Examples of the hole transporting material which may be contained in the liquid composition of the present invention include polyvinylcarbazole and derivatives thereof, polysilane and derivatives thereof, polysiloxane derivatives having an aromatic amine on the side chain or main chain, pyrazoline derivatives, arylamine derivatives, stilbene derivatives, triphenyldiamine derivatives, polyaniline and derivatives thereof, polythiophene and derivatives thereof, polypyrrole and derivatives thereof, poly(p-phenylenevinylene) and derivatives thereof, poly(2,5-thienylenevinylene) and derivatives thereof, and the like.

Examples of the electron transporting material which may be contained in the liquid composition of the present invention include oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivative, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof, polyfluorene and derivatives thereof, and the like.

Examples of the stabilizer which may be contained in the liquid composition of the present invention include phenol antioxidants, phosphorus antioxidants and the like.

As the additives for controlling viscosity and/or surface tension which may be contained in the liquid composition of the present invention, for example, a compound of high molecular weight for increasing viscosity (thickening agent) and a poor solvent, a compound of low molecular weight for decreasing viscosity, a surfactant for decreasing surface tension, and the like may be appropriately combined and used.

As the above-described compound of high molecular weight, those not disturbing light emission and charge transportation may be permissible, and usually, these are soluble in a solvent of the liquid composition. As the compound of high molecular weight, for example, polystyrene of high molecular weight, polymethyl methacrylate of high molecular weight, and the like can be used. The above-described compound of high molecular weight has a polystyrene-reduced number average molecular weight of preferably 500000 or more, more preferably 1000000 or more. Also a poor solvent can be used as a thickening agent.

As the antioxidant which may be contained in the liquid composition of the present invention, those not disturbing light emission and charge transportation may be permissible, and when the composition contains a solvent, these are usually soluble in the solvent. As the antioxidant, phenol antioxidants, phosphorus antioxidants and the like are illustrated. By use of the antioxidant, preservation stability of the above-described polymer compound and solvent can be improved.

When the liquid composition of the present invention contains a hole transporting material, the proportion of the hole transporting material in the liquid composition is usually 1 wt % to 80 wt %, preferably 5 wt % to 60 wt %. When the liquid composition of the present invention contains an electron transporting material, the proportion of the electron transporting material in the liquid composition is usually 1 wt % to 80 wt %, preferably 5 wt % to 60 wt %.

In the case of film formation using this liquid composition in producing a polymer light emitting device, it may be advantageous to only remove a solvent by drying after application of the liquid composition, and also in the case of mixing of a charge transporting material and a light emitting material, the same means can be applied, that is, this method is extremely advantageous for production. In drying, drying may be effected under heating at about from 50 to 150° C., alternatively, drying may be carried out under reduced pressure of about 10⁻³ Pa.

As the film formation method using a liquid composition, application methods such as a spin coat method, casting method, micro gravure coat method, gravure coat method, bar coat method, roll coat method, wire bar coat method, dip coat method, spray coat method, screen printing method, flexo printing method, offset printing method, inkjet print method and the like can be used.

The proportion of a solvent in the liquid composition is usually from 1 wt % to 99.9 wt %, preferably 60 wt % to 99.9 wt %, further preferably 90 wt % to 99.8 wt % with respect to the total weight of the liquid composition. Though the viscosity of the liquid composition varies with a printing method, the viscosity at 25° C. is preferably in a range of 0.5 to 500 mPa·s, and when a liquid composition passes through a discharge apparatus such as in an inkjet print method and the like, the viscosity at 25° C. is preferably in a range of 0.5 to 20 mPa·s, for preventing clogging and flying curving in discharging.

As the solvent contained in the liquid composition, those capable of dissolving or dispersing components other than the solvent in the liquid composition are preferable. Examples of the solvent include chlorine-based solvents such as chloroform, methylene chloride, 1,2-dichloroethane, 1,1,2-trichloroethane, chlorobenzene, o-dichlorobenzene and the like, ether solvents such as tetrahydrofuran, dioxane and the like, aromatic hydrocarbon solvents such as xylene, trimethylbenzene, mesitylene and the like, aliphatic hydrocarbon solvents such as cyclohexane, methylcyclohexane, n-pentane, n-hexane, n-heptane, n-octane, n-nonane, n-decane and the like, ketone solvents such as acetone, methyl ethyl ketone, cyclohexanone and the like, ester solvents such as ethyl acetate, butyl acetate, methyl benzoate, ethylcellosolve acetate and the like, polyhydric alcohols and derivatives thereof such as ethylene glycol, ethylene glycol monobutyl ether, ethylene glycol monoethyl ether, ethylene glycol monomethyl ether, dimethoxyethane, propylene glycol, diethoxymethane, triethylene glycol monoethyl ether, glycerin, 1,2-hexane diol and the like, alcohol solvent such as methanol, ethanol, propanol, isopropanol, cyclohexanol and the like, sulfoxide solvents such as dimethyl sulfoxide and the like, amide solvents such as N-methyl-2-pyrrolidone, N,N-dimethylformamide, and the like. These solvents may be used singly or in combination of two or more. Among the above-described solvents, one or more organic solvents having a structure containing at least one benzene ring and having a melting point of 0° C. or lower and a boiling point of 100° C. or higher are preferably contained from the standpoint of viscosity, film formability and the like.

Regarding the kind of the solvent, aromatic hydrocarbon solvents, aliphatic hydrocarbon solvents, ester solvents and ketone solvents are preferable from the standpoint of solubility of components other than the solvent in a liquid composition into the organic solvent, uniformity in film formation, viscosity property and the like, and preferable are toluene, xylene, ethylbenzene, diethylbenzene, trimethylbenzene, mesitylene, n-propylbenzene, i-propylbenzene, n-butylbenzene, i-butylbenzene, s-butylbenzene, anisole, ethoxybenzene, 1-methylnaphthalene, cyclohexane, cyclohexanone, cyclohexylbenzene, bicyclohexyl, cyclohexenylcyclohexanone, n-heptylcyclohexane, n-hexylcyclohexane, methylbenzoate, 2-propylcyclohexanone, 2-heptanone, 3-heptanone, 4-heptanone, 2-octanone, 2-nonanone, 2-decanone and dicyclohexyl ketone, and it is more preferable to contain at least one of xylene, anisole, mesitylene, cyclohexylbenzene and bicyclohexylmethyl benzoate.

The number of the solvents to be contained in the liquid composition is preferably 2 or more, more preferably 2 to 3, further preferably 2 from the standpoint of film formability and from the standpoint of a device property and the like.

When two solvents are contained in a liquid composition, one of them may be solid at 25° C. From the standpoint of film formability, it is preferable that one solvent has a boiling point of 180° C. or higher and another solvent has a boiling point of lower than 180° C., and it is more preferable that one solvent has a boiling point of 200° C. or higher and another solvent has a boiling point of lower than 180° C. From the standpoint of viscosity, it is preferable that 0.2 wt % or more of components excepting solvents from a liquid composition are dissolved at 60° C. in solvents, and it is preferable that 0.2 wt % or more of components excepting solvents from a liquid composition are dissolved at 25° C. in one of two solvents.

When three solvents are contained in a liquid composition, one or two of them may be solid at 25° C. From the standpoint of film formability, it is preferable that at least one of three solvents has a boiling point of 180° C. or higher and at least one solvent has a boiling point of lower than 180° C., and it is more preferable that at least one of three solvents has a boiling point of 200° C. or higher and 300° C. or lower and at least one solvent has a boiling point of lower than 180° C. From the standpoint of viscosity, it is preferable that 0.2 wt % or more of components excepting solvents from a liquid composition are dissolved at 60° C. in two or three solvents, and it is preferable that 0.2 wt % or more of components excepting solvents from a liquid composition are dissolved at 25° C. in one of three solvents.

When two or more solvents are contained in a liquid composition, the content of a solvent having highest boiling point is preferably from 40 to 90 wt %, more preferably 50 to 90 wt %, further preferably 65 to 85 wt % based on the weight of all solvents contained in the liquid composition, from the standpoint of viscosity and film formability.

### —Thin Film—

The thin film of the present invention will be illustrated. This thin film contains the above-described polymer compound. Examples of the thin film include light emitting thin films, electric conductive thin films, organic semiconductor thin films and the like.

The light emitting thin film has a quantum yield of light emission of preferably 50% or more, more preferably 60% or more, further preferably 70% or more from the standpoint of the luminance, light emission voltage and the like of a device.

The electric conductive thin film preferably has a surface resistance of 1 KΩ/□ or less. By doping a thin film with a Lewis acid, ionic compound or the like, electric conductivity can be enhanced. The surface resistance is preferably 100 Ω/□ or less, further preferably 10 Ω/□ or less.

In the organic semiconductor thin film, one larger parameter of electron mobility or hole mobility is preferably 10⁻⁵ cm²/V/s or more, more preferably 10⁻³ cm²/V/s or more, and further preferably 10⁻¹ cm²/V/s or more. Using an organic semiconductor thin film, an organic transistor can be manufactured. Specifically, by forming the organic semiconductor thin film on a Si substrate carrying a gate electrode and an insulation film of SiO₂ and the like formed thereon, and forming a source electrode and a drain electrode with Au and the like, an organic transistor can be obtained.

### —Organic Transistor (Polymer Electric Field Effect Transistor)—

Next, a polymer electric field effect transistor as one embodiment of organic transistors will be described. This organic transistor contains a polymer compound of the present invention.

The polymer compound of the present invention can be suitably used as a material of a polymer electric field effect transistor, particularly, as an active layer. Regarding the structure of a polymer electric field effect transistor, it may be usually advantageous that a source electrode and a drain electrode are placed close to an active layer made of a polymer, further, a gate electrode is placed sandwiching an insulation layer close to the active layer.

The polymer electric field effect transistor is usually formed on a supporting substrate. The material of the supporting substrate is not particularly restricted providing it does not disturb a property as an electric field effect transistor, and glass substrates and flexible film substrates and plastic substrates can also be used.

The polymer electric field effect transistor can be produced by known methods, for example, a method described in JP-A No. 5-110069.

It is very advantageous and preferable to use a polymer compound soluble in an organic solvent, in forming an active layer. As a method of film formation from a solution prepared by dissolving an organic solvent-soluble polymer compound in a solvent, application methods such as a spin coat method, casting method, micro gravure coat method, gravure coat method, bar coat method, roll coat method, wire bar coat method, dip coat method, spray coat method, screen printing method, flexo printing method, offset printing method, inkjet printing method and the like can be used.

Preferable is an encapsulated polymer electric field effect transistor obtained by manufacturing a polymer electric field effect transistor, then, encapsulating this is preferable. By this, the polymer electric field effect transistor is blocked from atmosphere, thereby, lowering of properties of the polymer electric field effect transistor can be suppressed.

As the encapsulation method, a method of covering with an ultraviolet (UV) hardening resin, thermosetting resin, or inorganic SiONx film and the like, a method of pasting a glass plate or film with an UV hardening resin, thermosetting resin or the like, and other methods are mentioned. For effectively performing blocking from atmosphere, it is preferable that processes after manufacturing of a polymer electric field effect transistor until encapsulation are carried out without exposing to atmosphere (for example, in dried nitrogen gas atmosphere, vacuum and the like).

### —Organic Solar Battery—

Next, the organic solar battery will be described. This organic solar battery contains a polymer compound of the present invention. A solid photoelectric conversion device utilizing a photoelectromotive force effect as an organic photoelectric conversion device as one embodiment of the organic solar battery will be described.

The polymer compound of the present invention can be suitably used as a material of an organic photoelectric conversion device, particularly, as an organic semiconductor layer of a schottky barrier type device utilizing an interface between an organic semiconductor and a metal, or as an organic semiconductor layer of a pn hetero junction type device utilizing an interface between an organic semiconductor and an inorganic semiconductor or between organic semiconductors.

Further, the polymer compound of the present invention can be suitably used as an electron donating polymer or an electron accepting polymer in a bulk hetero junction type device in which the donor-acceptor contact area is increased, or an electron donating conjugated polymer (dispersion supporting body) of an organic photoelectric conversion device using a high molecular weight-low molecular weight complex system, for example, a bulk hetero junction type organic photoelectric conversion device containing a dispersed fullerene derivative as an electron acceptor.

With respect to the structure of the organic photoelectric conversion device, in the case of for example a pn hetero junction type device, it is advantageous that a p type semiconductor layer is formed on an ohmic electrode, for example, on ITO, further, an n type semiconductor layer is laminated, and an ohmic electrode is placed thereon.

The organic photoelectric conversion device is usually formed on a supporting substrate. The material of the supporting substrate is not particularly restricted providing it does not disturb a property as an organic photoelectric conversion device, and glass substrates and flexible film substrates and plastic substrates can also be used.

The organic photoelectric conversion device can be produced by known methods, for example, a method described in Synth. Met., 102, 982 (1999), and a method described in Science, 270, 1789 (1995).

### <Polymer Light Emitting Device>

Next, the polymer light emitting device of the present invention will be described.

The polymer light emitting device of the present invention contains electrodes composed of an anode and a cathode, and a light emitting layer having the above-described polymer compound placed between the electrodes. The polymer light emitting device of the present invention includes a polymer light emitting device further having an electron transporting layer placede between a cathode and a light emitting layer; a polymer light emitting device further having a hole transporting layer placed between an anode and a light emitting layer; a polymer light emitting device further having an electron transporting layer placed between a cathode and a light emitting layer and having a hole transporting layer placed between an anode and a light emitting layer; and the like.

As specific structures of the polymer light emitting device of the present invention, for example, the following a) to d) are illustrated.

a) anode/light emitting layer/cathode
b) anode/hole transporting layer/light emitting layer/cathode
c) anode/light emitting layer/electron transporting layer/cathode
d) anode/hole transporting layer/light emitting layer/electron transporting layer/cathode

(wherein, / means adjacent lamination of layers, applicable also in the following descriptions.)

“Light emitting layer” is a layer having a function of emitting light. “Hole transporting layer” is a layer having a function of transporting holes. “Electron transporting layer” is a layer having a function of transporting electrons. The electron transporting layer and hole transporting layer are collectively called a charge transporting layer. These light emitting layer, hole transporting layer and electron transporting layer may be each independently used singly, or two or more layers may be used.

Though the method of film formation of a light emitting layer is not restricted, for example, methods of film formation from a solution are mentioned. “Method by film formation from a solution” applied for film formation of a light emitting layer is a method in which a solution prepared by dissolving a polymer compound of the present invention in a solvent such as, for example, toluene, xylene, mesitylene, decalin, limonene and the like is applied by the following application method to form a film.

For the method by film formation from a solution, application methods such as, for example, a spin coat method, casting method, micro gravure coat method, gravure coat method, bar coat method, roll coat method, wire bar coat method, dip coat method, spray coat method, screen printing method, flexo printing method, offset printing method, inkjet print method and the like can be used.

In the case of firm formation from a solution using a polymer compound of the present invention in producing a polymer light emitting device, it may be advantageous to only remove a solvent by drying after application of the resultant solution, and also in the case of mixing of a charge transporting material and a light emitting material, the same means can be applied, that is, this method is extremely advantageous for production.

The thickness of a light emitting layer shows an optimum value varying with a material to be used, and may be advantageously regulated so as to give desired values of driving voltage and light emission efficiency, and is, for example, 1 nm to 1 μm, preferably 2 nm to 500 nm, further preferably 5 nm to 200 nm.

In the polymer light emitting device of the present invention, a light emitting material other than the above-described polymer compound may be mixed in a light emitting layer. Further, the light emitting layer containing a light emitting material other than the above-described polymer compound may be laminated to a light emitting layer containing the above-described polymer compound.

As the light emitting material other than the above-described polymer compound, known materials such as compounds of low molecular weight, and the like can be used. Examples of the compounds of low molecular weight include naphthalene derivatives, anthracene or derivatives thereof, perylene or derivatives thereof, coloring matters such as polymethines, xanthenes, coumarins and cyanines, metal complexes of 8-hydroxyquinoline or derivatives thereof, aromatic amines, tetraphenylcyclopentadiene or derivatives thereof, tetraphenylbutadiene or derivatives thereof, and the like. Specifically, known materials such as those described, for example, in JP-A Nos. 57-51781, 59-194393, and the like can be used.

As the above-described light emitting material, metal complexes showing light emission from triplet excited state (triplet light emitting complex: including also complexes showing phosphorescence emission, or fluorescence emission in addition to this phosphorescence emission), those conventionally used as EL light emitting materials of low molecular weight, and the like can also be used. These triplet light emitting complexes are disclosed in, for example, Nature, (1998), 395, 151, Appl. Phys. Lett. (1999), 75(1), 4, Proc. SPIE-Int. Soc. Opt. En g (2001), 4105 (Organic Light-Emitting Materials and Devices IV), 119, J. Am. Chem. Soc., (2001), 123, 4304, Appl. Phys. Lett., (1997), 71(18), 2596, Syn. Met., (1998), 94(1), 103, Syn. Met., (1999), 99(2), 1361, Adv. Mater., (1999), 11(10), 852, and the like.

When the polymer light emitting device of the present invention contains a hole transporting layer (usually, the hole transport layer contains a hole transporting material of low molecular weight or high molecular weight), examples of the hole transporting material to be used include polyvinylcarbazole or its derivatives, polysilane or its derivatives, polysiloxane derivatives having an aromatic amine on the side chain or main chain, pyrazoline derivatives, arylamine derivatives, stilbene derivatives, triphenyldiamine derivatives, polyaniline or its derivatives, polythiophene or its derivatives, polypyrrole or its derivatives, poly(p-phenylenevinylene) or its derivatives, poly(2,5-thienylenevinylene) or its derivatives, and the like. Specifically, hole transporting materials described in JP-A Nos. 63-70257, 63-175860, 2-135359, 2-135361, 2-209988, 3-37992 and 3-152184, and the like, are illustrated.

Among them, preferable as the hole transporting material used in a hole transporting layer are hole transporting materials of high molecular weight such as polyvinylcarbazole or its derivatives, polsilane or its derivatives, polysiloxane derivatives having an aromatic amine compound group on the side chain or main chain, polyaniline or its derivatives, polythiophene or its derivatives, poly(p-phenylenevinylene) or its derivatives, poly(2,5-thienylenevinylene) or its derivatives, and the like, and further preferable are polyvinylcarbazole or its derivatives, polsilane or its derivatives, and polysiloxane derivatives having an aromatic amine on the side chain or main chain. When the hole transporting material to be used is of low molecular weight, it is preferable that the hole transporting material is dispersed in a polymer binder in use.

Polyvinylcarbazole or its derivative is obtained, for example, from a vinyl monomer by cation polymerization or radical polymerization.

As the polysilane or its derivative, compounds described in Chem. Rev., vol. 89, p. 1359 (1989), GB Patent No. 2300196 publication, and the like are illustrated. Also as the synthesis method, methods described in them can be used, and particularly, the Kipping method is suitably used.

In the polysiloxane or its derivative, the siloxane skeleton structure shows little hole transporting property, thus, those having a structure of the above-mentioned hole transporting material of low molecular weight on the side chain or main chain are suitably used. Particularly, those having an aromatic amine showing a hole transporting property on the side chain or main chain are illustrated.

The film formation method of a hole transporting layer is not particularly restricted, and in the case of use of a hole transporting material of low molecular weight, a method of film formation from a mixed solution with a polymer binder is illustrated. In the case of use of a hole transporting material of high molecular weight, a method of film formation from a solution is illustrated.

The solvent used for film formation from a solution is not particularly restricted providing it can dissolve a hole transporting material and/or polymer binder. Examples of the solvent include chlorine-based solvents such as chloroform, methylene chloride, dichloroethane and the like, ether solvents such as tetrahydrofuran and the like, aromatic hydrocarbon solvents such as toluene, xylene and the like, ketone solvents such as acetone, methyl ethyl ketone and the like, ester solvents such as ethyl acetate, butyl acetate, ethylcellosolve acetate and the like.

As the method for film formation from a solution, there can be used application methods from a solution such as a spin coat method, casting method, micro gravure coat method, gravure coat method, bar coat method, roll coat method, wire bar coat method, dip coat method, spray coat method, screen printing method, flexo printing method, offset printing method, inkjet print method and the like.

As the above-described polymer binder, those not extremely disturbing charge transportation are preferable, and those showing no strong absorption against visible light are suitably used. Examples of the polymer binder are polycarbonate, polyacrylate, polymethyl acrylate, polymethyl methacrylate, polystyrene, polyvinyl chloride, polysiloxane and the like.

Regarding the thickness of a hole transporting layer, the optimum value varies with a material to be used, and it may be advantageously selected so that the driving voltage and light emission efficiency become optimum, and a thickness at least causing no formation of pin holes is necessary, and when the thickness is too large, the driving voltage of a device increases undesirably. Therefore, the thickness of the hole transporting layer is, for example, 1 nm to 1 μm, preferably 2 nm to 500 nm, further preferably 5 nm to 200 nm.

When the polymer light emitting device of the present invention has an electron transporting layer (usually, the electron transporting layer contains an electron transporting material of low molecular weight or high molecular weight), known materials can be used as the electron transporting material to be used, and illustrated are oxadiazole derivatives, anthraquinodimethane or its derivatives, benzoquinone or its derivatives, naphthoquinone or its derivatives, anthraquinone or its derivatives, tetracyanoanthraquinodimethane or its derivatives, fluorenone derivatives, diphenyldicyanoethylene or its derivatives, diphenoquinone derivatives, metal complexes of 8-hydroxyquinoline or its derivatives, polyquinoline or its derivatives, polyquinoxaline or its derivatives, polyfluorene or its derivatives, and the like. Specifically, electron transporting materials described in JP-A Nos. 63-70257, 63-175860, 2-135359, 2-135361, 2-209988, 3-37992 and 3-152184, and the like are illustrated.

Of them, oxadiazole derivatives, benzoquinone or its derivatives, anthraquinone or its derivatives, metal complexes of 8-hydroxyquinoline or its derivatives, polyquinoline or its derivatives, polyquinoxaline or its derivatives, polyfluorene or its derivatives are preferable, and 2-(4-biphenylyl)-5-(4-t-butylphenyl)-1,3,4-oxadiazole, benzouqinone, anthraquinone, tris(8-quinolinol)aluminum and polyquinoline are further preferable.

The film formation method of an electron transporting layer is not particularly restricted, and in the case of use of an electron transporting material of low molecular weight, illustrated are a vacuum vapor-deposition method from powder, film formation methods from solution or melted conditions, and in the case of use of an electron transporting material of high molecular weight, film formation methods from solution or melted condition are illustrated, respectively. In film formation from solution or melted condition, the polymer binder may be used together.

The solvent used for film formation from a solution is not particularly restricted providing it can dissolve an electron transporting material and/or polymer binder. Examples of the solvent include chlorine-based solvents such as chloroform, methylene chloride, dichloroethane and the like, ether solvents such as tetrahydrofuran and the like, aromatic hydrocarbon solvents such as toluene, xylene and the like, ketone solvents such as acetone, methyl ethyl ketone and the like, ester solvents such as ethyl acetate, butyl acetate, ethylcellosolve acetate and the like.

As the film formation method from solution or melted condition, application methods such as, for example, a spin coat method, casting method, micro gravure coat method, gravure coat method, bar coat method, roll coat method, wire bar coat method, dip coat method, spray coat method, screen printing method, flexo printing method, offset printing method, inkjet printing method and the like can be used.

As the above-described polymer binder, those not extremely disturbing charge transportation are preferable, and those showing no strong absorption against visible light are suitably used. Examples of the polymer binder include poly(N-vinylcarbazole), polyaniline or derivatives thereof, polythiophene or derivatives thereof, poly(p-phenylenevinylene) or derivatives thereof, poly(2,5-thienylenevinylene) or derivatives thereof, polycarbonate, polyacrylate, polymethyl acrylate, polymethyl methacrylate, polystyrene, polyvinyl chloride, polysiloxane and the like.

Regarding the thickness of an electron transporting layer, the optimum value varies with a material to be used, and it may be advantageously selected so that the driving voltage and light emission efficiency become optimum, and a thickness at least causing no formation of pin holes is necessary, and when the thickness is too large, the driving voltage of a device increases undesirably. Therefore, the thickness of the electron transporting layer is, for example, 1 nm to 1 μm, preferably 2 nm to 500 nm, further preferably 5 nm to 200 nm.

Among charge transporting layers placed adjacent to an electrode, those having a function of improving charge injection efficiency from an electrode and having an effect of lowering the driving voltage of a device are, in particularly, called generally a charge injection layer (hole injection layer, electron injection layer).

Further, for improving close adherence with an electrode or improving charge injection from an electron, the above-mentioned charge injection layer or an insulation layer (usually, having an average film thickness of 0.5 mm to 4 mm, also in the following descriptions) may be placed adjacent to the electrode, or for improving close adherence of an interface or preventing mixing, a thin buffer layer may be inserted into an interface of a charge transporting layer and a light emitting layer.

The order and number of layers to be laminated, and thickness of each layer may be appropriately determined in view of light emission efficiency and device life.

In the present invention, as the polymer light emitting device carrying a placed charge injection layer (electron injection layer, hole injection layer), mentioned are polymer light emitting devices having a charge injection layer placed adjacent to a cathode and polymer light emitting devices having a charge injection layer placed adjacent to an anode.

Specific structures of the polymer light emitting device of the present invention also include, for example, the following e) to p).

e) anode/charge injection layer/light emitting layer/cathode

f) anode/light emitting layer/charge injection layer/cathode

g) anode/charge injection layer/light emitting layer/charge injection layer/cathode

h) anode/charge injection layer/hole transporting layer/light emitting layer/cathode

i) anode/hole transporting layer/light emitting layer/charge injection layer/cathode

j) anode/charge injection layer/hole transporting layer/light emitting layer/charge injection layer/cathode

k) anode/charge injection layer/light emitting layer/electron transporting layer/cathode

l) anode/light emitting layer/electron transporting layer/charge injection layer/cathode

m) anode/charge injection layer/light emitting layer/electron transporting layer/charge injection layer/cathode

n) anode/charge injection layer/hole transporting layer/light emitting layer/charge transporting layer/cathode

o) anode/hole transporting layer/light emitting layer/electron transporting layer/charge injection layer/cathode

p) anode/charge injection layer/hole transporting layer/light emitting layer/electron transporting layer/charge injection layer/cathode

Examples of the charge injection layer, include a layer containing an electric conductive polymer, a layer placed between an anode and a hole transporting layer and containing a material having ionization potential of a value between an anode material and a hole transporting material contained in a hole transporting layer, a layer containing a material having electron affinity of a value between a cathode material and an electron transporting material contained in an electron transporting layer, and the like.

When the above-mentioned charge injection layer contains an electric conductive polymer, electric conductivity of the electric conductive polymer is preferably 10⁻⁵ S/cm or more and 103 or less, and for decreasing leak current between light emission picture elements, more preferably 10⁻⁵ S/cm or more and 102 or less, further preferably 10⁻⁵ S/cm or more and 101 or less.

Usually, for controlling the electric conductivity of the electric conductive polymer to 10⁻⁵ S/cm or more and 103 or less, the electric conductive polymer is doped with a suitable amount of electrons.

As the kind of ions to be doped, an anion is used in a hole injection layer and a cation is used in an electron injection layer. Examples of the anion include a polystyrenesulfonic ion, alkylbenzenesulfonic ion, camphorsulfonic ion and the like, and examples of the cation include a lithium ion, sodium ion, potassium ion, tetrabutylammonium ion and the like.

The thickness of the charge injection layer is, for example, 1 nm to 100 nm, preferably 2 nm to 50 nm.

The material used in the charge injection layer may be appropriately selected depending on a relation with materials of an electrode and an adjacent layer, and specifically illustrated are electric conductive polymers such as polyaniline or its derivatives, polythiophene or its derivatives, polypyrrole and its derivatives, polyphenylenevinylene and its derivatives, polythienylenevinylene and its derivatives, polyquinoline and its derivatives, polyquinoxaline and its derivatives, polymers containing an aromatic amine structure on the main chain or side chain, and the like, and metal phthalocyanines (copper phthalocyanine and the like), carbon and the like.

The insulation layer has a function of making charge injection easier. As the material of this insulation layer, for example, metal fluorides, metal oxides, organic insulating materials and the like are mentioned. As the polymer light emitting device carrying an insulation layer placed thereon, there are mentioned polymer light emitting devices in which an insulation layer is placed adjacent to a cathode, and polymer light emitting devices in which an insulation layer is placed adjacent to an anode.

Specific structures of the polymer light emitting device of the present invention also include, for example, the following q) to ab).

q) anode/insulation layer/light emitting layer/cathode

r) anode/light emitting layer/insulation layer/cathode

s) anode/insulation layer/light emitting layer/insulation layer/cathode

t) anode/insulation layer/hole transporting layer/light emitting layer/cathode

u) anode/hole transporting layer/light emitting layer/insulation layer/cathode

v) anode/insulation layer/hole transporting layer/light emitting layer/insulation layer/cathode

w) anode/insulation layer/light emitting layer/electron transporting layer/cathode

x) anode/light emitting layer/electron transporting layer/insulation layer/cathode

y) anode/insulation layer/light emitting layer/electron transporting layer/insulation layer/cathode

z) anode/insulation layer/hole transporting layer/light emitting layer/electron transporting layer/cathode

aa) anode/hole transporting layer/light emitting layer/electron transporting layer/insulation layer/cathode

ab) anode/insulation layer/hole transporting layer/light emitting layer/electron transporting layer/insulation layer/cathode

The substrate which forms a polymer light emitting device of the present invention may advantageously be that forming an electrode and which does not change in forming a layer of an organic substance, and examples thereof include substrates of glass, plastic, polymer film, silicon and the like. In the case of an opaque substrate, it is preferable that the opposite electrode is transparent or semi-transparent.

In the present invention, usually, at least one of electrodes composed of an anode and cathode is transparent or semi-transparent, and it is preferable that a cathode is transparent or semi-transparent.

As the material of the anode, for example, an electric conductive metal oxide film, semi-transparent metal thin film and the like are used. Specifically, films (NESA and the like) formed using electric conductive glass composed of indium oxide, zinc oxide, tin oxide, and composite thereof: indium.tin.oxide (ITO), indium.zinc.oxide and the like, gold, platinum, silver, copper and the like are used, and ITO, indium.zinc.oxide, tin oxide are preferable. As the anode manufacturing method, a vacuum vapor-deposition method, sputtering method, ion plating method, plating method and the like are mentioned. As the anode, organic transparent electric conductive films made of polyaniline or its derivative, polythiophene or its derivative, and the like may be used.

The thickness of an anode can be appropriately selected in view of light transmission and electric conductivity, and it is, for example, 10 nm to 10 μm, preferably 20 nm to 1 μm, further preferably 50 nm to 500 nm.

For making electric charge injection easier, a layer made of a phthalocyanine derivative, electric conductive polymer, carbon and the like, or an insulation layer made of a metal oxide, metal fluoride, organic insulation material and the like, may be placed on an anode.

As the material of a cathode used in a polymer light emitting device of the present invention, materials of small work function are preferable. For example, metals such as lithium, sodium, potassium, rubidium, cesium, beryllium, magnesium, calcium, strontium, barium, aluminum, scandium, vanadium, zinc, yttrium, indium, cerium, samarium, europium, terbium, ytterbium and the like, alloys of two or more of them, or alloys made of at least one of them and at least one of gold, silver, platinum, copper, manganese, titanium, cobalt, nickel, tungsten and tin, graphite or graphite intercalation compounds and the like are used. Examples of the alloy include magnesium-silver alloy, magnesium-indium alloy, magnesium-aluminum alloy, indium-silver alloy, lithium-aluminum alloy, lithium-magnesium alloy, lithium-indium alloy, calcium-aluminum alloy and the like. The cathode may take a laminated structure including two or more layers.

The thickness of a cathode can be appropriately selected in view of electric conductivity and durability, and it is, for example, 10 nm to 10 μm, preferably 20 nm to 1 μm, further preferably 50 nm to 500 nm.

As the cathode manufacturing method, a vacuum vapor-deposition method, sputtering method, lamination method of thermally press-binding a metal thin film, and the like are used. A layer made of an electric conductive polymer, or a layer made of a metal oxide, metal fluoride, organic insulation material and the like, may be placed between a cathode and an organic substance layer, and after manufacturing a cathode, a protective layer for protecting the polymer light emitting device may be installed. For use of the polymer light emitting device stably for a long period of time, it is preferable to install a protective layer and/or protective cover, for protecting a device from outside.

As the protective layer, polymers (for example, gas barriering polymers such as polyvinylidene fluoride and its copolymers, polyesters, polyacrylonitrile, aromatic polyamides, liquid crystal polyesters and the like), metal oxides, metal fluorides, metal borides and the like can be used. As the protective cover, a glass plate, and a plastic plate having a surface which has been subjected to low water permeation treatment, and the like can be used. As the method of protecting a device with a protective cover, preferable is a method in which the cover is pasted to a device substrate with a thermosetting resin or photo-curing resin to attain sealing is preferable. When a space is kept using a spacer, blemishing of a device can be prevented easily. If an inert gas such as nitrogen, argon and the like is filled in this space, oxidation of a cathode can be prevented, further, by placing a drying agent such as barium oxide and the like in this space, it becomes easier to suppress moisture adsorbed in a production process from imparting damage to the device. It is preferable to adopt one strategy among these methods.

### —Application of Polymer Light Emitting Device—

The polymer light emitting device of the present invention is useful, for example, for a sheet light source, a display such as a flat panel display, segment display, dot matrix display, liquid crystal display and the like, or back light thereof.

For obtaining light emission in the form of sheet using a polymer light emitting device of the present invention, it may be advantages to place a sheet anode and a sheet cathode so as to overlap. For obtaining light emission in the form of pattern, there are a method in which a mask having a window in the form of pattern is placed on the surface of the above-mentioned sheet light emitting device, a method in which an organic substance layer in non-light emitting parts is formed with extremely large thickness to give substantially no light emission, a method in which either anode or cathode, or both electrodes are formed in the form pattern. By forming a pattern by any of these methods, and placing several electrodes so that on/off is independently possible, a display of segment type is obtained which can display digits, letters, simple marks and the like. Further, for providing a dot matrix device, it may be permissible that both an anode and a cathode are formed in the form of stripe, and placed so as to cross. By using a method in which several polymer compounds showing different emission colors are painted separately or a method in which a color filter or a fluorescence conversion filter is used, partial color display and multi-color display are made possible. In the case of a dot matrix device, passive driving is possible, and active driving may be carried out in combination with TFT and the like. These displays can be used as a display of a computer, television, portable terminal, cellular telephone, car navigation, view finder of video camera, and the like.

Further, the above-mentioned sheet light emitting diode is of self emitting and thin type, and can be suitably used as a sheet light source for back light of a liquid crystal display, or as a sheet light source for illumination. If a flexible substrate is used, it can also be used as a curved light source or display.

Examples will be shown below for illustrating the present invention further in detail, but the present invention is not limited to them. The molecular weight of a compound measured in examples is polystyrene-reduced number average molecular weight or weight average molecular weight measured by gel permeation chromatography (GPC) using tetrahydrofuran as a solvent. Measurement of glass transition temperature (Tg) was carried out by differential scanning colorimetry (DSC, trade name: DSC2920, manufactured by TA Instruments). Specifically, a sample is kept at 200° C. for 5 minutes, then, quenched down to −50° C. and kept for 30 minutes. Then, the temperature was raised up to 30° C., then, measurement was carried out at a temperature rising rate of 5° C. per minute up to 300° C.

### SYNTHESIS EXAMPLE 1

Into a solution prepared by dissolving 1.54 g of a phosphonate obtained by reacting 2-bromomethyl-1,4-dibromobenzene and triethyl phosphate, and 1.1 g of 2-(diphenylphosphino)benzaldehyde in 30 g of tetrahydrofuran (dehydrated), a solution prepared previously by dissolving 0.7 g of potassium-t-butoxide in 10 g tetrahydrofuran (dehydrated) was dropped at room temperature. After dropping, they were reacted subsequently at room temperature for 10 hours. The reaction was carried out in a nitrogen gas atmosphere.

After completion of the reaction, acetic acid was added to the resultant reaction solution to neutralize the reaction solution, then, the solution was poured into methanol, to cause re-deposition. The produced precipitate was filtrated and recovered. This precipitate was washed with methanol, then, dried under reduced pressure, to obtain 0.75 g of a monomer (PP-TPP) (specific structure thereof is as described later).

MS (APPI (+)): (M+H)⁺ 523

### EXAMPLE 1

### monomer (1)

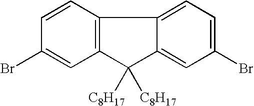

monomer (PP-TPP)

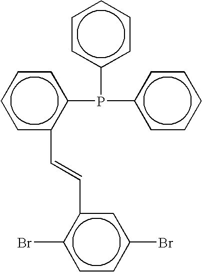

### —Synthesis of Polymer Compound 1—

0.58 g of a monomer (1) (manufactured by JFE Chemical), 0.23 g of a monomer (PP-TPP) and 0.66 g of 2,2′-bipyridyl were charged in a reaction vessel, then, an atmosphere in the reaction system was purged with a nitrogen gas. To this was added 70 g of tetrahydrofuran (dehydrated solvent) previously deaerated by bubbling with an argon gas. Then, to the resultant mixed solution was added 1.15 g of bis(1,5-cyclooctadiene)nickel(0) and the mixture was stirred at room temperature for 10 minutes, then, reacted at 60° C. for 3 hours. The reaction was carried out under a nitrogen gas atmosphere.

After completion of the reaction, this reaction solution was cooled. Then, into the resultant reaction solution, a mixed solution of methanol 60 ml/ion exchanged water 60 ml was poured, and the mixture was stirred for about 1 hour. Then, the produced precipitate was filtrated and recovered. This precipitate was dried under reduced pressure, then, dissolved in toluene. The resultant toluene solution was filtrated to remove insoluble materials, then, the toluene solution was washed with a ca. 1 N hydrochloric acid aqueous solution, and allowed to stand still to cause liquid separation, then, the toluene solution was recovered. The recovered toluene solution was washed with a ca. 3 wt % ammonia water, and allowed to stand still to cause liquid separation, then, the toluene solution was recovered. Then, the recovered toluene solution was washed with ion exchanged water, and allowed to stand still to cause liquid separation, then, the toluene solution was recovered. Next, the recovered toluene solution was poured into methanol to cause re-precipitation purification. Next, the produced precipitate was recovered, and washed with methanol, then, this precipitate was dried under reduced pressure to obtain 0.07 g of a polymer. This polymer is called polymer compound 1. The resultant polymer compound 1 had a polystyrene-reduced weight average molecular weight of 1.5×10⁴ and a number average molecular weight of 7.7×10³. The glass transition temperature (Tg) thereof was 71° C.

The structures of repeating units contained in the polymer compound 1 estimated from charging are shown below. The polymer compound 1 is constituted of a repeating unit A and a repeating unit B (=7:3 molar ratio)(estimated from charging).

Repeating Unit A

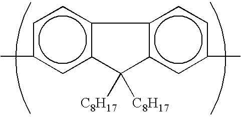

Repeating Unit B

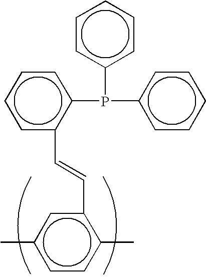

### SYNTHESIS EXAMPLE 2

### Synthesis of Monomer (2)

### Synthesis of Compound a

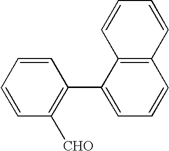

Under an inert atmosphere, into a 300 ml three-necked flask was charged 5.00 g (29 mmol) of 1-naphthaleneboronic acid, 6.46 g (35 mmol) of 2-bromobenzaldehyde, 10.0 g (73 mmol) of potassium carbonate, 36 mol of toluene and 36 ml of ion exchanged water, and argon was bubble through the mixture for 20 minutes while stirring at room temperature. Then, 16.8 mg (0.15 mmol) of tetrakis(triphenylphosphine)palladium was added, and argon was bubble through the mixture further for 10 minutes while stirring at room temperature. The mixture was heated up to 100° C., and reacted for 25 hours. After cooling to room temperature, an organic layer was extracted with toluene, dried over sodium sulfate, then, the solvent was distilled off. The product was purified by a silica gel column using a toluene:cyclohexane=1:2 (volume ratio) mixed solvent as a development solvent, to obtain 5.18 g (yield: 86%) of a compound a as white crystal.

¹H-NMR (300 MHz/CDCl₃):

δ 7.39 to 7.62 (m, 5H), 7.70 (m, 2H), 7.94 (d, 2H), 8.12 (dd, 2H), 9.63 (s, 1H)

MS (APCI(+)): (M+H)⁺ 233

### Synthesis of Compound b

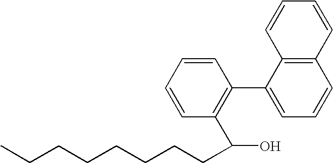

Under an inert atmosphere, into a 300 ml three-necked flask was charged 8.00 g (34.4 mmol) of the compound a and 46 ml of dehydrated THF and the mixture was cooled down to −78° C. Then, 52 ml of n-octylmagnesium bromide (1.0 mol/l THF solution) was dropped over a period of 30 minutes. After completion of dropping, the mixture was heated up to 0° C., stirred for 1 hour, then, heated up to room temperature and stirred for 45 minutes. In an ice bath, 20 ml of 1 N hydrochloric acid was added to terminate the reaction, an organic layer was extracted with ethyl acetate, and dried over sodium sulfate. The solvent was distilled off, then, the product was purified by a silica gel column using a toluene:hexane=10:1 (volume ratio) mixed solvent as a development solvent, to obtain 7.64 g (yield: 64%) of a compound b as pale yellow oil. Two peaks were observed in HPLC measurement, however, the same mass number was observed in LC-MS measurement, leading to judgment of a mixture of isomers.

### Synthesis of Compound c

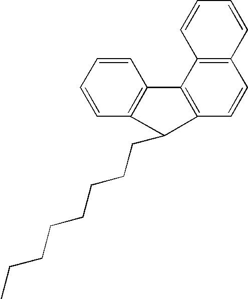

Under an inert atmosphere, into a 500 ml three-necked flask was charged 5.00 g (14.4 mmol) of the compound b (mixture of isomers) and 74 ml of dehydrated dichloromethane, and the mixture was stirred at room temperature, leading to dissolution. Then, an etherate complex of boron trifluoride was dropped at room temperature over 1 hours, and after completion of dropping, the mixture was stirred at room temperature for 4 hours. 125 ml of ethanol was slowly added while stirring, and when heat generation completed, an organic layer was extracted with chloroform, washed with water twice, and dried over magnesium sulfate. Then solvent was distilled off, then, the product was purified by a silica gel column using hexane as a development solvent, to obtain 3.22 g (yield: 68%) of a compound c as colorless oil.

¹H-NMR (300 MHz/CDCl₃):

δ 0.90 (t, 3H), 1.03 to 1.26 (m, 14H), 2.13 (m, 2H), 4.05 (t, 1H), 7.35 (dd, 1H), 7.46 to 7.50 (m, 2H), 7.59 to 7.65 (m, 3H), 7.82 (d, 1H), 7.94 (d, 1H), 8.35 (d, 1H), 8.75 (d, 1H)

MS (APCI (+)): (M+H)⁺ 329

### Synthesis of Compound d

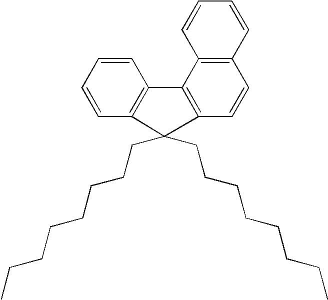

Under an inert atmosphere, into a 200 ml three-necked flask was charged 20 ml of ion exchanged water, and 18.9 g (0.47 mol) of sodium hydroxide was added portion-wise while stirring, leading to dissolution. After the aqueous solution was cooled to room temperature, 20 mol of toluene, 5.17 g (15.7 mmol) of the compound c and 1.52 g (4.72 mmol) of tributylammonium bromide were added, and the mixture was heated up to 50° C. n-octyl bromide was dropped, and after completion of dropping, the mixture was reacted at 50° C. for 9 hours. After completion of the reaction, an organic layer was extracted with toluene, washed with water twice, and dried over sodium sulfate. The product was purified by a silica gel column using hexane as a development solvent, to obtain 5.13 g (yield: 74%) of a compound d as yellow oil.

¹H-NMR (300 MHz/CDCl₃):

δ 0.52 (m, 2H), 0.79 (t, 6H), 1.00 to 1.20 (m, 22H), 2.05 (t, 4H), 7.34 (d, 1H), 7.40 to 7.53 (m, 2H), 7.63 (m, 3H), 7.83 (d, 1H), 7.94 (d, 1H), 8.31 (d, 1H), 8.75 (d, 1H)

MS (APCI(+)): (M+H)⁺ 441

### Synthesis of Compound e

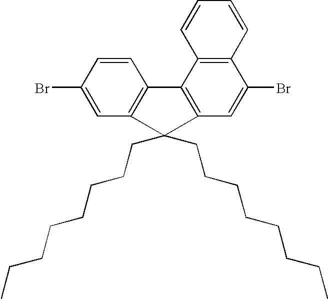

Under an inert atmosphere, into a 50 ml three-necked flask was charged 4.00 g (9.08 mmol) of the compound d and 57 ml of an acetic acid:dichloromethane=1:1 (volume ratio) mixed solvent, and the mixture was stirred at room temperature, leading to dissolution. Then, 7.79 g (20.0 mmol) of benzyltrimethylammonium tribromide was added, and zinc chloride was added while stirring until complete dissolution of benzyltrimethylammonium tribromide. The mixture was stirred at room temperature for 20 hours, then, 10 ml of a 5 wt % sodium hydrogen sulfite aqueous solution was added to stop the reaction, an organic layer was extracted with chloroform, washed with a potassium carbonate aqueous solution twice, and dried over sodium sulfate. The product was purified twice by a flush column using hexane as a development solvent and silica gel as a filler, then, re-crystallized from an ethanol:hexane=1:1 (volume ratio) mixed solvent, subsequently, from a 10:1 (volume ratio) mixed solvent, to obtain 4.13 g (yield: 76%) of a compound e as while crystal.

¹H-NMR (300 MHz/CDCl₃):

δ 0.60 (m, 2H), 0.91 (t, 6H), 1.01 to 1.38 (m, 22H), 2.09 (t, 4H), 7.62 to 7.75 (m, 3H), 7.89 (s, 1H), 8.20 (d, 1H), 8.47 (d, 1H), 8.72 (d, 1H)

MS (APPI (+)): (M+H)⁺ 598

Thus obtained compound e is called monomer (2).

### Monomer (2)

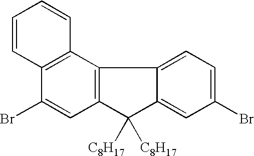

### EXAMPLE 2

### Synthesis of Polymer Compound 2

0.63 g of a monomer (2), 0.23 g of a monomer (PP-TPP) and 0.66 g of 2,2′-bipyridyl were charged in a reaction vessel, then, an atmosphere in the reaction system was purged with a nitrogen gas. To this was added 70 g of tetrahydrofuran (dehydrated solvent) previously deaerated by bubbling with an argon gas. To the resultant mixed solution was added 1.15 g of bis(1,5-cyclooctadiene)nickel(0) and the mixture was stirred at room temperature for 10 minutes, then, reacted at 60° C. for 3 hours. The reaction was carried out under a nitrogen gas atmosphere.

After completion of the reaction, this reaction solution was cooled. Then, into this solution, a mixed solution of methanol 40 ml/ion exchanged water 40 ml was poured, and the mixture was stirred for about 1 hour. Then, the produced precipitate was filtrated and recovered. This precipitate was dried under reduced pressure, then, dissolved in toluene. The resultant toluene solution was filtrated to remove insoluble materials, then, this toluene solution was washed with a ca. 1 N hydrochloric acid aqueous solution, and allowed to stand still to cause liquid separation, then, the toluene solution was recovered. The, this toluene solution was washed with a ca. 3 wt % ammonia water, and allowed to stand still to cause liquid separation, then, the toluene solution was recovered. The recovered toluene solution was washed with ion exchanged water, and allowed to stand still to cause liquid separation, then, the toluene solution was recovered. Next, the recovered toluene solution was poured into methanol to cause re-precipitation purification. Next, the produced precipitate was recovered, and washed with methanol, then, this precipitate was dried under reduced pressure to obtain 0.05 g of a polymer. This polymer is called polymer compound 2. The resultant polymer compound 2 had a polystyrene-reduced weight average molecular weight of 1.0×10⁴ and a number average molecular weight of 5. 9×10³. The glass transition temperature (Tg) thereof was 101° C.

The structures of repeating units contained in the polymer compound 2 estimated from charging are shown below. The polymer compound 2 is constituted of a repeating unit C and a repeating unit B (=7:3 molar ratio)(estimated from charging).

Repeating Unit C

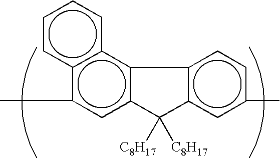

Repeating Unit B

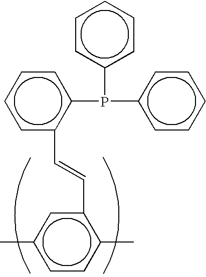

### SYNTHESIS EXAMPLE 3

### Synthesis of Monomer (F-TPP)

1.95 g of a monomer raw material (A) of the following structural formula and 1.16 g of 2-(diphenylphosphino)benzaldehyde (manufactured by Aldrich) were charged in a reaction vessel, then, an atmosphere in the reaction system was purged with a nitrogen gas.

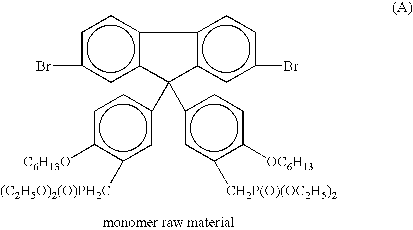

To this was added 50 ml of tetrahydrofuran (dehydrated). Into the resultant mixed solution, a solution prepared by previously dissolving 0.67 g of potassium-t-butoxide in 5 ml of tetrahydrofuran (dehydrated) was dropped at room temperature. After cropping, the mixture was subsequently reacted at room temperature for 24 hours. The reaction was carried out under a nitrogen gas atmosphere.

After completion of the reaction, acetic acid was added to the resultant reaction solution to neutralize the reaction solution, then, methanol was added to this. Next, the solvent was distilled off under reduced pressure from this solution. The resultant solid was washed with methanol, then, filtrated and a precipitate was recovered. This precipitate was dissolved in toluene. This toluene solution was filtrated to remove insoluble materials, then, the resultant toluene solution was purified by passing through an alumina column. Next, the solvent was distilled off under reduced pressure from this toluene solution. The resultant product was washed with methanol, then, dried under reduced pressure to obtain 1.3 g of a monomer (F-TPP)(specific structure thereof is as described later).

### EXAMPLE 3

### Synthesis of Polymer Compound 3

0.81 g of a monomer (2), 0.19 g of a monomer (F-TPP) of the following structural formula and 0.57 g of 2,2′-bipyridyl were charged in a reaction vessel, then, an atmosphere in the reaction system was purged with a nitrogen gas.

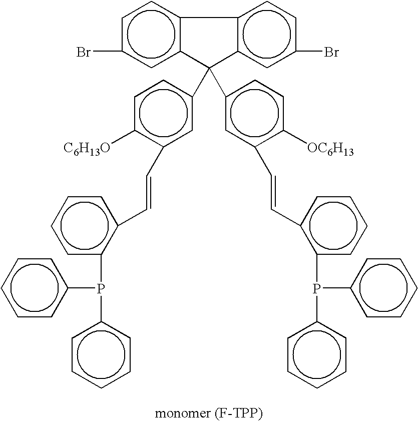

To this was added 60 g of tetrahydrofuran (dehydrated solvent) previously deaerated by bubbling with an argon gas. To the resultant mixed solution was added 1.0 g of bis(1,5-cyclooctadiene)nickel(0) and the mixture was reacted at room temperature for 23 hours. The reaction was carried out under a nitrogen gas atmosphere.

After completion of the reaction, this reaction solution was poured into a mixed solution of methanol 40 ml/ion exchanged water 40 ml to cause re-precipitation, and subsequently, the mixture was stirred for about 1 hour. Next, the produced precipitate was filtrated and recovered. This precipitate was dried under reduced pressure, then, dissolved in toluene. This toluene solution was filtrated to remove insoluble materials, then, this toluene solution was washed with a ca. 5 wt % acetic acid aqueous solution, and allowed to stand still to cause liquid separation, thereafter, the toluene solution was recovered. Next, this toluene solution was washed with 4 wt % ammonia water, and allowed to stand still to cause liquid separation, then, the toluene solution was recovered. The recovered toluene solution was washed with ion exchanged water, and allowed to stand still to cause liquid separation, then, the toluene solution was recovered. Next, the recovered toluene solution was poured into methanol to cause re-precipitation purification. Next, the produced precipitate was recovered, and washed with methanol, then, this precipitate was dried under reduced pressure to obtain 0.23 g of a polymer. This polymer is called polymer compound 3. The resultant polymer compound 3 had a polystyrene-reduced weight average molecular weight of 70×10⁴ and a polystyrene-reduced number average molecular weight of 2.2×10⁴. The glass transition temperature (Tg) thereof was 121° C.

The structures of repeating units contained in the polymer compound 3 estimated from charging are shown below. The polymer compound 3 is constituted of a repeating unit C and a repeating unit F (=9:1 molar ratio) (estimated from charging).

Repeating Unit C

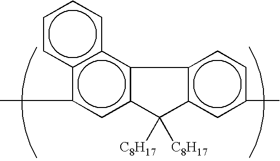

Repeating Unit F

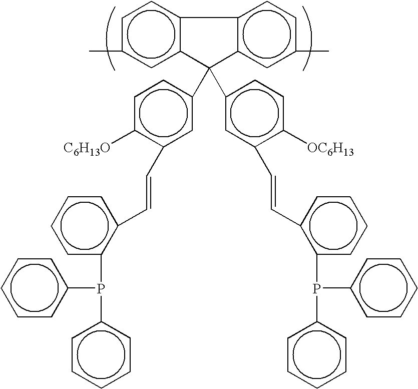

### SYNTHESIS EXAMPLE 4

### Synthesis of Monomer (F-TPA)

1.95 g of a monomer raw material (A) and 1.09 g of 4-(N,N-diphenylamino)benzaldehyde (manufactured by Tokyo Kasei sha) were charged in a reaction vessel, then, an atmosphere in the reaction system was purged with a nitrogen gas. To this was added 50 ml of tetrahydrofuran (dehydrated). Into the resultant mixed solution, a solution prepared by previously dissolving 0.67 g of potassium-t-butoxide in 5 ml of tetrahydrofuran (dehydrated) was dropped at room temperature. After cropping, the mixture was subsequently reacted at room temperature for 24 hours. The reaction was carried out under a nitrogen gas atmosphere.

After completion of the reaction, acetic acid was added to the resultant reaction solution to neutralize the reaction solution, then, methanol was added to this. Next, the solvent was distilled off under reduced pressure from this solution. The resultant solid was washed with methanol, then, filtrated and a precipitate was recovered. This precipitate was dissolved in toluene. This toluene solution was filtrated to remove insoluble materials, then, the resultant toluene solution was purified by passing through an alumina column. Next, the solvent was distilled off under reduced pressure from this toluene solution. The resultant product was washed with methanol, then, dried under reduced pressure to obtain 1.6 g of a monomer (F-TPA) of the following structural formula.

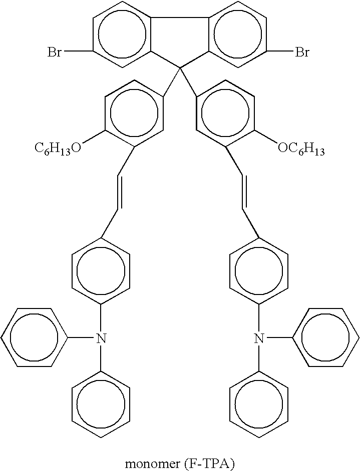

### COMPARATIVE EXAMPLE 1

### Synthesis of Polymer Compound 4

0.81 g of a monomer (2), 0.18 g of the above-described monomer (F-TPA) and 0.57 g of 2,2′-bipyridyl were charged in a reaction vessel, then, an atmosphere in the reaction system was purged with a nitrogen gas. To this was added 60 g of tetrahydrofuran (dehydrated solvent) previously deaerated by bubbling with an argon gas. To the resultant mixed solution was added 1.0 g of bis(1,5-cyclooctadiene)nickel(0) and the mixture was reacted at room temperature for 23 hours. The reaction was carried out under a nitrogen gas atmosphere.

After completion of the reaction, this reaction solution was poured into a mixed solution of methanol 40 ml/ion exchanged water 40 ml to cause re-precipitation, and subsequently, the mixture was stirred for about 1 hour. Next, the produced precipitate was filtrated and recovered. This precipitate was dried under reduced pressure, then, dissolved in toluene. This toluene solution was filtrated to remove insoluble materials, then, this toluene solution was washed with a ca. 5 wt % acetic acid aqueous solution, and allowed to stand still to cause liquid separation, thereafter, the toluene solution was recovered. Next, this toluene solution was washed with 4 wt % ammonia water, and allowed to stand still to cause liquid separation, then, the toluene solution was recovered. The recovered toluene solution was washed with ion exchanged water, and allowed to stand still to cause liquid separation, then, the toluene solution was recovered. Next, the recovered toluene solution was poured into methanol to cause re-precipitation purification. Next, the produced precipitate was recovered, and washed with methanol, then, this precipitate was dried under reduced pressure to obtain 0.31 g of a polymer. This polymer is called polymer compound 4. The resultant polymer compound 4 had a polystyrene-reduced weight average molecular weight of 3.1×10⁵ and a number average molecular weight of 6.9×10⁴. The glass transition temperature (Tg) thereof was 128° C.

The structures of repeating units contained in the polymer compound 4 estimated from charging are shown below. The polymer compound 4 is constituted of a repeating unit C and a repeating unit G (=9:1 molar ratio)(estimated from charging).

repeating unit C

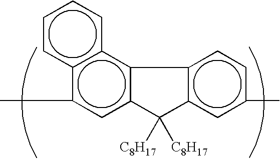

Repeating Unit G

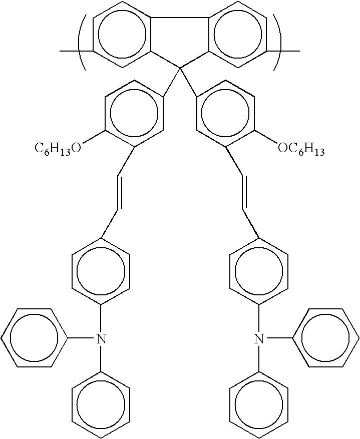

### <Evaluation of Fluorescent Property>

Using the polymer compounds 1 to 6, a 0.8 wt % toluene solution of the polymer compound was spin-coated on a quartz plate to form a thin film of the polymer compound. The fluorescent spectrum of this thin film was measured using a fluorescence spectrophotometer (manufactured by JOBINYVON-SPEX, trade name: Fluorolog) at an excitation wavelength of 350 nm. For obtaining relative fluorescence intensity on the thin film, fluorescent spectrum plotted against wave number was integrated in the spectrum measuring range utilizing the intensity of Raman line of water as a standard, and measurement was performed using a spectrophotometer (Cary 5E, manufactured Varian), obtaining a value allocated to the absorbance at the excited wavelength.

Measured results of the fluorescence peak wavelength and fluorescence intensity are shown in Table 1. The polymer compound 3 of the present invention showed stronger fluorescence intensity than that of the polymer compound 4 having a triphenylamine structure on the side chain.

TABLE 1

| | fluorescence | fluorescence |
|---|---|---|
| | peak | intensity |
| | wavelength | (relative |
| | (nm) | intensity) |
| polymer | 421 | 5.6 |
| compound 1 | | |
| polymer | 449 | 6.3 |
| compound 2 | | |
| polymer | 450 | 9.1 |
| compound 3 | | |
| polymer | 450 | 7.3 |
| compound 4 | | |

### EXAMPLE 4

### Manufacturing of Device and Evaluation Thereof

A 1.5 wt % xylene solution of a mixture of the polymer compound 1 and an iridium complex A of the following structural formula (2 wt % with respect to the polymer compound 2) was prepared.

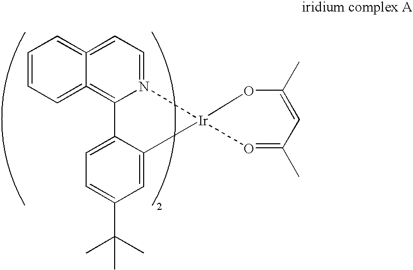

On a glass substrate carrying thereon an ITO film with a thickness of 150 nm formed by a sputtering method, a solution of poly(ethylenedioxythiophene)/polystyrenesulfonic acid (Bayer, BaytronP) was spin-coated to form a film with a thickness of 50 nm, and dried on a hot plate at 200° C. for 10 minutes. Next, the xylene solution prepared above was spin-coated at a rotation rate of 800 rpm to form a film. The film thickness was about 70 nm. This was dried at 130° C. under a nitrogen gas atmosphere for 1 hour, then, as a cathode, barium was vapor-deposited with a thickness of about 5 nm, then aluminum was vapor-deposited with a thickness of about 80 nm, to manufacture an EL device. After the degree of vacuum reached 1×10⁻⁴ Pa or less, vapor-deposition of a metal was initiated.

By applying voltage on the resultant EL device, strong EL light emission (peak wavelength: 630 nm) from the iridium complex was obtained. The device showed light emission of a luminance of 100 cd/m² at an applied voltage of 9.2 V, and the maximum luminance was as high as about 240 cd/m².

### EXAMPLE 5

A 1.5 wt % xylene solution of a mixture of the polymer compound 2 and the iridium complex A (2 wt % with respect to the polymer compound 2) was prepared, and an EL device was manufactured in the same manner as in Example 4. A light emitting layer was formed by spin coat at a rotation rate of 800 rpm. The film thickness was about 70 nm. By applying voltage on the resultant device, strong EL light emission (peak wavelength: 635 nm) from the iridium complex was obtained. The device showed light emission of a luminance of 100 cd/m² at an applied voltage of 10.4 V, and the maximum luminance was as high as about 160 cd/m².

### EXAMPLE 6

### Preparation of Solution

The polymer compound 3 obtained above was dissolved in xylene to prepare a xylene solution having a polymer concentration of 1.8 wt %.

### —Manufacturing of EL Device—

On a glass substrate carrying thereon an ITO film with a thickness of 150 nm formed by a sputtering method, a solution prepared by filtrating a suspension of poly(3,4)ethylenedioxythiophene/polystyrenesulfonic acid (manufactured by Bayer, BaytronP CH8000) through a 0.2 μm membrane filter was spin-coated to form a thin film with a thickness of 60 nm, and dried on a hot plate at 200° C. for 10 minutes. Next, the xylene solution obtained above was spin-coated at a rotation rate of 3200 rpm to form a film. The thickness after film formation was about 70 nm. Further, this was dried at 80° C. under reduced pressure for 1 hour, then, as a cathode, barium was vapor-deposited with a thickness of about 5 nm, then, aluminum was vapor-deposited with a thickness of about 80 nm, to manufacture an EL device. After the degree of vacuum reached 1×10⁻⁴ Pa or less, vapor-deposition of a metal was initiated.

### —Ability of EL Device—

By applying voltage on the resultant device, EL light emission showing a peak at 450 nm was obtained from this device. C.I.E. color coordinate values of EL light emission color at a luminance of 100 cd/m² were x=0.161 and y=0.139. The intensity of EL light emission was in approximate proportion to the current density. This device showed initiation of light emission from an applied voltage of 4.2 V, and the maximum light emission efficiency was 0.20 cd/A.

### INDUSTRIAL APPLICABILITY

The polymer compound of the present invention is particularly useful as a light emitting material, and has excellent heat resistance and fluorescence intensity. A polymer light emitting device using this polymer compound has high performances (for example, high luminance, high light emission efficiency), and is useful particularly for a sheet light source, display and the like. Further, this polymer compound can be used also in an organic transistor and solar battery.

1. A polymer compound comprising a repeating unit of the following formula (1):
—[Ar₁—(X₁)ₙ]— (1)
wherein, Ar₁ represents an arylene group having a group of the following formula (2), a divalent heterocyclic group having a group of the following formula (2) or a divalent aromatic amine group having a group of the following formula (2), X₁ represents —CR¹═CR²—, wherein, R¹ and R² represent each independently a hydrogen atom, alkyl group, aryl group, monovalent heterocyclic group or cyano group) or —C≡C—, and n represents 0 or 1, 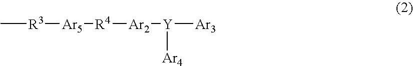
wherein, Ar₂ represents an arylene group, divalent heterocyclic group or divalent aromatic amine group, Ar₅ represents a direct bond, arylene group, divalent heterocyclic group or divalent aromatic amine group, R³ and R⁴ represent each independently a direct bond, —R⁵—, —O—R⁵—, —R⁵—O—, —R⁵—C(O)O—, —R⁵—OC(O)—, —R⁵—N(R⁶)—, —O—, —S—, —C(O)O—, —C(O)—, —CR⁷═CR⁸— or —C≡C— wherein, R⁵ represents an alkylene group or alkenylene group, R⁶, R⁷ and R⁸ represent each independently a hydrogen atom, alkyl group, aryl group, monovalent heterocyclic group or cyano group, Ar₃ and Ar₄ represent each independently an aryl group, monovalent heterocyclic group or monovalent aromatic amine group, and Y represents: 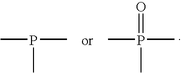
here, when Ar₅ is a direct bond, R³ is a direct bond.

2. The polymer compound according to claim 1, wherein said Ar₁ is a divalent group of the following formula (8): 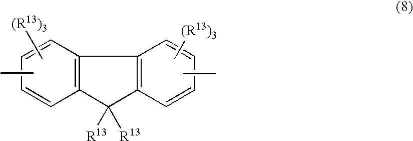
wherein, R¹³ represents a group of said formula (2), hydrogen atom, alkyl group, alkoxy group, alkylthio group, alkylsilyl group, alkylamino group, aryl group, aryloxy group, arylalkyl group, arylalkoxy group, arylalkenyl group, arylalkynyl group, arylamino group, monovalent heterocyclic group or cyano group, or, two or more of R₁₃s may be connected to form an aromatic ring or non-aromatic ring, two or more of R₁₃s may be the same as or different from each other, here, the formula (8) has at least one group of said formula.

3. The polymer compound according to claim 1, wherein said Ar₁ is a divalent group of the following formula (9): 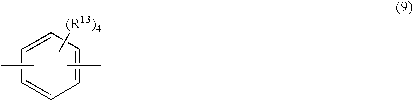
wherein, R¹³ is the same as described above, here, the formula (9) has at least one group of said formula.

4. The polymer compound according to claim 1, further comprising a repeating unit of the following formula (10):
—[Ar₁₉—(X₂)ₚ]— (10)
wherein, Ar₁₉ represents an arylene group, divalent heterocyclic group, divalent aromatic amine group or divalent aromatic phosphine group, X₂ represents —CR¹⁴═CR¹⁵—, here, R¹⁴ and R¹⁵ represent each independently a hydrogen atom, alkyl group, aryl group, monovalent heterocyclic group or cyano group, or —C≡C—, and p represents 0 or 1.

5. The polymer compound according to claim 4, wherein said Ar₁₉ is a divalent group of any of the following formulae (2a) to (2d): 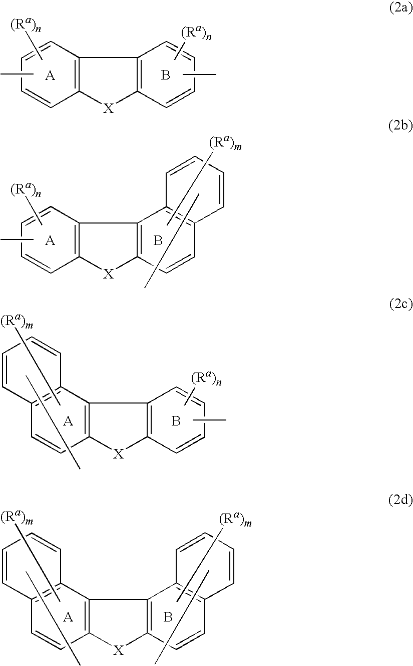
wherein, X represents an atom or divalent group forming a 5-membered ring or 6-membered ring together with two atoms on a ring A and two atoms on a ring B, R^{a} represents a substituent, m's represent independently an integer of 0 to 5, and n's represent independently an integer of 0 to 3, when there are two or more of R^{a}s, they may be the same as or different from each other.

6. The polymer compound according to claim 5, wherein in said formulae (2a) to (2d), X is —C(R¹⁸)(R¹⁹)—, —C(R²⁰)(R²¹)—C(R²²)(R²³)—, —O—, —S— or —N(R²⁴)—, wherein R¹⁸, R¹⁹, R²⁰, R²¹, R²² and R²³ represent each independently a hydrogen atom, alkyl group, alkoxy group, alkylthio group, alkylsilyl group, alkylamino group, aryl group, aryloxy group, arylalkyl group, arylalkoxy group, arylalkenyl group, arylalkynyl group, arylamino group, monovalent heterocyclic group or cyano group, R²⁴ represents a hydrogen atom, alkyl group, aryl group, arylalkyl group or monovalent heterocyclic group.

7. The polymer compound according to claim 1, having a polystyrene-reduced number average molecular weight of 1×10³ to 1×10⁸.

8. A light emitting material comprising the polymer compound as described in claim 1.

9. A polymer light emitting device having electrodes composed of an anode and a cathode, and a light emitting layer placed between the electrodes and containing the polymer compound as described in claim 1.

10. A sheet light source, using the polymer light emitting device as described in claim 9.

11. A display, using the polymer light emitting device as described in claim 9.

12. A liquid composition comprising the polymer compound as described in claim 1 and a solvent.

13. A thin film comprising the polymer compound as described in claim 1.

14. An organic transistor comprising the polymer compound as described in claim 1.

15. A solar battery comprising the polymer compound as described in claim 1.
